(19) United States
(12) Patent Application Publication
(10) Pub. No.: US 2009/0174002 A1
(43) Pub. Date: Jul. 9, 2009

(54) MOSFET HAVING A HIGH STRESS IN THE CHANNEL REGION

(75) Inventors: Qiqing Ouyang, Yorktown Heights, NY (US); Kathryn T. Schonenberg, Wappingers Falls, NY (US); John Yates, III, Cornwall on Hudson, NY (US)

Correspondence Address: SCULLY, SCOTT, MURPHY & PRESSER, P.C., 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 11/971,437

(22) Filed: Jan. 9, 2008

(51) Int. Cl. H01L 21/8238; H01L 27/092

(52) U.S. Cl. 257/369; 438/231; 257/E21.633; 257/E27.062

(57) ABSTRACT

Source and drain extension regions are selectively removed by a dopant concentration dependent etch or a doping type dependent etch, and an embedded stress-generating material such as SiGe alloy or a Si:C alloy in the source and drain extension regions is grown on a semiconductor substrate. The embedded stress-generating material may be grown only in the source and drain extension regions, or in the source and drain extension regions and in deep source and drain regions. In one embodiment, an etch process that removes doped semiconductor regions of one conductivity type selective to doped semiconductor regions of another conductivity type may be employed. In another embodiment, a dopant concentration dependent etch process that removes doped semiconductor regions irrespective of the conductivity type selective to undoped semiconductor regions may be employed.

### FIELD OF THE INVENTION

The present invention relates to high-performance semiconductor devices for digital or analog applications, and more particularly to complementary metal oxide semiconductor (CMOS) devices that have stress induced mobility enhancement. Specifically, the present invention provides stressed CMOS devices with embedded stress-inducing material in the source and drain extension regions that laterally protrude from deep source and drain regions toward a channel so that heterojunctions between two semiconductor materials coincide with, or are located in close proximity to, p-n junctions, and methods of manufacturing the same.

### BACKGROUND OF THE INVENTION

Various techniques for enhancing semiconductor device performance through manipulation of carrier mobility have been investigated in the semiconductor industry. One of the key elements in this class of technology is the manipulation of stress in the channel of transistor devices. Some of these methods utilize a carbon-substituted single crystal silicon (Si:C) layer within a silicon substrate to change the lattice constant of the silicon material in the channel. While both silicon and carbon have identical electronic outer shells and the same crystal structure, that is, “the diamond structure,” their room temperature lattice constants are different with values of 0.5431 nm and 0.357 nm, respectively. By substituting some of the silicon atoms in a single crystalline silicon lattice with carbon atoms, a single crystal structure with a smaller lattice constant than that of pure silicon may be obtained.

Such lattice mismatched materials may be advantageously employed to generate stress on a semiconductor device, for example, by applying biaxial stress or uniaxial stress in a channel region of a metal-oxide-semiconductor field effect transistor (MOSFET) to improve performance, for example, by increasing an on-current. The effect of uniaxial stress, i.e., a stress applied along one crystallographic orientation, on the performance of semiconductor devices, especially on the performance of a MOSFET (or a “FET” in short) device built on a silicon substrate, has been extensively studied in the semiconductor industry. For a p-type MOSFET (or a “PFET” in short) utilizing a silicon channel, the mobility of minority carriers in the channel (which are holes in this case) increases under uniaxial compressive stress along the direction of the channel, i.e., the direction of the movement of holes or the direction connecting the drain to the source. Conversely, for an n-type MOSFET (or an “NFET” in short) devices utilizing a silicon channel, the mobility of minority carriers in the channel (which are electrons in this case) increases under uniaxial tensile stress along the direction of the channel, i.e., the direction of the movement of electrons or the direction connecting the drain to the source. These opposite requirements for the type of stress for enhancing carrier mobility between the PFETs and NFETs have led to prior art methods for applying at least two different types of stress to the semiconductor devices on the same integrated chip.

For PFETs formed on a silicon substrate, formation of a SiGe alloy embedded in a source and drain has been demonstrated as effective means of introducing compressive uniaxial stress in a channel region to enhance performance of a p-type MOSFET. Similarly, formation of a Si:C alloy embedded in a source and drain has been demonstrated as effective means of introducing tensile uniaxial stress in a channel region to enhance performance of an n-type MOSFET.

While the etch profile of the recessed region may be anisotropic or isotropic depending on the chemistry employed in the etch process, a source and drain region of a silicon substrate is typically recessed by an isotropic dry etch such as an in-situ etch employing HCl at about 700° C. in an epitaxial process chamber prior to a selective epitaxy of silicon. In order to generate high stress in the channel area, and thus enhance performance of a MOSFET significantly, embedded SiGe alloys or embedded Si:C alloys in the source and drain region must be formed in close proximity to the channel region. The closer the embedded SiGe alloys or the embedded Si:C alloys are to the center of the channel region, the higher the stress and the strain in the channel. Thus, it is preferable that the etch profile of the silicon recess process be very close to the channel region.

However, forming such an etch profile in the recessed region poses a challenge in processing. One typical problem is that the amount of lateral recess is linearly proportional to the vertical etch depth during an isotropic etch, for either a dry etch or a wet etch. In order to have a large amount of lateral etch (so that the edge of the recessed region is formed closer to the channel region), a deep vertical etch is required. While this technique may be used for silicon recess in bulk devices which have relatively deep source and drain regions, it is not suitable for SOI devices. High performance CMOS devices including an SOI substrate employ a top semiconductor layer having a thickness from about 40 nm to about 100 nm. Another typical problem of currently known etching techniques is a loading effect, in which the etch profile depends on pattern density, i.e., a local areal density of etchable materials. A third typical problem is that the etch profile of an isotropic or anisotropic recess etch may contain crystallographic facets formed on the surfaces of the recessed regions, which poses a challenge for a subsequent epitaxial growth of embedded materials.

While an anisotropic etch may be employed instead of an isotropic etch to form the recessed regions, achieving close proximity of stress-generating embedded material regions to the channel region by the anisotropic etch requires formation of an extremely thin gate spacer having a well-controlled thickness as well as tight control of the anisotropic etch process. In this case, a very tight control of thickness is required on a very thin film, typically having a thickness from about 10 nm to about 20 nm. Further, such a reactive ion etch process may potentially have a very small process window.

In view of the above, there exists a need for a semiconductor structure in which stress-generating embedded semiconductor regions are formed in close proximity to a channel region of a MOSFET, and methods of manufacturing the same.

Further, there exists a need for a semiconductor structure in which the lateral recess in the source and drain region at the step of recess formation is controlled by a self-limiting or self-aligning etching mechanism, and consequently having a self-aligned stress-generating embedded semiconductor region that provides a controlled high level of stress and strain to a channel region of a MOSFET, and methods of manufacturing the same.

### SUMMARY OF THE INVENTION

To address the needs described above, the present invention provides a semiconductor structure having stress-generating embedded source and drain regions that are self-aligned to halo regions and methods of manufacturing the same.

In the current invention, methods of selectively removing source and drain extension regions and growing an embedded stress-generating material such as SiGe alloy or a Si:C alloy in the source and drain extension regions are provided. The embedded stress-generating material may be grown only in the source and drain extension regions, or in the source and drain extension regions and in deep source and drain regions. In one embodiment, an etch process that removes doped semiconductor regions of one conductivity type selective to doped semiconductor regions of another conductivity type may be employed. In another embodiment, a dopant concentration dependent etch process that removes doped semiconductor regions irrespective of the conductivity type selective to undoped or lightly doped semiconductor regions may be employed.

An advantage of the present invention is that etch process is self-aligning to the edges of the source and drain extension regions so that the etch profile is better controlled and is independent of pattern density of the etched regions, i.e., loading effects are minimized resulting in improved uniformity of etch relative to prior art etch processes.

Further, an abrupt junction profile may be obtained since the sharpness of the boundaries between the source and drain extension regions is not limited by thermal diffusion but may be formed by an abrupt interface introduced by in-situ doped epitaxy. Alternatively, the dopants may be introduced into the source and drain regions and the deep source and drain regions by an intrinsic epitaxial deposition followed by a dopant implantation and an anneal. The embedded stress-generating material may provide additional advantages of suppressing dopant diffusion resulting in an abrupt dopant profile in source and drain extension regions and/or deep source and drain regions containing some stress-generating alloys. For example, boron diffusion is reduced significantly in SiGeC alloys and phosphorus diffusion is suppressed in Si:C alloys. The abrupt junction profile reduces short-channel effects and series resistance in the source and drain extension regions and/or the deep source and drain regions.

Yet another advantage of the present invention is that heterojunctions (junctions between two heterogeneous semiconductor materials) between the semiconductor material comprising a body of a MOSFET and the embedded stress-generating materials are in close proximity to the p-n junctions (metallurgical junctions formed at the boundary between two semiconductor regions having opposite dopant types). It has been shown that the junction leakage remains low and a hetero-barrier can help reduce drain induced barrier lowering (DIBL) and an off-current as long as the heterojunction is contained in close proximity of the p-n junction.

According to an aspect of the present invention, a semiconductor structure is provided, which comprises:

a semiconductor substrate containing a first semiconductor material and including a body having a doping of a first conductivity type, wherein the body abuts a top surface of the semiconductor substrate;

a gate electrode including a gate dielectric and a gate conductor, wherein the gate dielectric vertically abuts the body;

at least one gate spacer surrounding and laterally abutting the gate electrode and vertically abutting the top surface of the semiconductor substrate;

a source extension region and a drain extension region, each of which comprising a second semiconductor material, having a doping of a second conductivity type, located in the semiconductor substrate, abutting the gate dielectric, extending to a first depth into the semiconductor substrate from the top surface into the semiconductor substrate, and self-aligned to one of gate electrode sidewalls, wherein the second semiconductor material is different from the first semiconductor material; and

a deep source region and a deep drain region, each of which having a doping of the second conductivity type, located in the semiconductor substrate, laterally abutting one of the source extension region and the drain extension region, extending to a second depth from the top surface into the semiconductor substrate, and self-aligned to one of gate spacer outer sidewalls, wherein the second depth is greater than the first depth.

In one embodiment, the deep source region laterally abuts the source extension region, the deep drain region laterally abuts the drain extension region, and the source extension region and the drain extension region have a width that is substantially equal to a width of the at least one gate spacer.

In another embodiment, the deep source region and the deep drain region comprise the second semiconductor material.

In even another embodiment, the deep source region comprises a vertical stack of a top source region and a bottom source region and the deep drain region comprises a vertical stack of a top drain region and a bottom drain region, wherein each of the top source region and the top drain region comprises the second semiconductor material and extends from the top surface of the semiconductor substrate to the first depth, and wherein each of the bottom source region and the bottom drain region comprises the first semiconductor material and extends from the first depth to the second depth.

In yet another embodiment, each of the deep source region and the deep drain region contains the second semiconductor material.

In still another embodiment, the first semiconductor material is silicon and the second semiconductor material is one of a silicon germanium alloy, a silicon carbon alloy, and a silicon carbon germanium alloy.

In still yet another embodiment, the semiconductor structure further comprises:

a source side halo region having a doping of the first conductivity type, located directly beneath the source extension region and the gate electrode, and self-aligned to one of the sidewalls of the gate electrode; and

a drain side halo region having a doping of the first conductivity type, located directly beneath the drain extension region and the gate electrode, and self-aligned to another of the sidewalls of the gate electrode.

In a further embodiment, each of the source extension region and the drain extension region abuts the body at a convexly arced surface extending from the gate dielectric to the first depth into the semiconductor substrate, wherein the convexly arced surface is free of crystallographic facets.

In an even further embodiment, the source extension region and the drain extension region generates stress in a channel located directly beneath the gate electrode and between the source extension region and the drain extension region, wherein the stress is a uniaxial stress in the direction connecting the source extension region and the drain extension region.

In a yet further embodiment, the semiconductor structure further comprises another semiconductor device located on the semiconductor substrate, the another semiconductor device comprising:

another body having a doping of the second conductivity type, wherein the another body abuts the top surface of the semiconductor substrate;

another gate electrode including another gate dielectric and another gate conductor, wherein the another gate dielectric vertically abuts the another body;

a source extension region and a drain extension region, each of which comprising the first semiconductor material, having a doping of the first conductivity type, located in the semiconductor substrate, abutting the another gate dielectric, and self-aligned to one of sidewalls of the another gate electrode; and

a deep source region and a deep drain region, each of which having a doping of the first conductivity type, located in the semiconductor substrate, laterally abutting one of the another source extension region and the another drain extension region, and self-aligned to one of sidewalls of another gate spacer on the another gate electrode,

In a still further embodiment, the semiconductor structure further comprises another semiconductor device located on the semiconductor substrate, the another semiconductor device comprising:

another body having a doping of the second conductivity type, wherein the another body abuts the top surface of the semiconductor substrate;

another gate electrode including another gate dielectric and another gate conductor, wherein the another gate dielectric vertically abuts the another body;

a source extension region and a drain extension region, each of which comprising a third semiconductor material, having a doping of the first conductivity type, located in the semiconductor substrate, abutting the another gate dielectric, and self-aligned to one of sidewalls of the another gate electrode, wherein the third semiconductor material is different from the first semiconductor material and the second semiconductor material; and

a deep source region and a deep drain region, each of which having a doping of the first conductivity type, located in the semiconductor substrate, laterally abutting one of the another source extension region and the another drain extension region, and self-aligned to one of outer sidewalls of another gate spacer on the another gate electrode.

According to another aspect of the present invention, a method of forming a semiconductor structure is provided, which comprises:

providing a semiconductor region comprising a first semiconductor material and having a doping of a first conductivity type in a semiconductor substrate;

forming a gate electrode containing a gate dielectric and a gate conductor on the semiconductor substrate;

forming a dummy source extension region and a dummy drain extension region by implanting dopants of a second conductivity type into the semiconductor region, wherein each of the dummy source extension region and the dummy drain extension region has a doping of the second conductivity type and extends from a top surface of the semiconductor substrate to a first depth, and wherein the second conductivity type is the opposite of the first conductivity type;

forming a source side halo region and a drain side halo region, each of which having a doping of the first conductivity type and extending from the top surface of the semiconductor substrate to a halo depth in the semiconductor region, wherein the halo depth is greater than the first depth, the source extension region abut the source side halo region, and the drain extension region abut the drain side halo region;

removing the dummy source extension region and the dummy drain extension region selective to the source side halo region and the drain side halo region; and

selectively depositing a second semiconductor material directly on the source side halo region and the drain side halo region, wherein the second semiconductor material is different from the first semiconductor material.

According to one embodiment of the present invention, the method further comprises:

forming a dummy deep source region and a dummy deep drain region, each of which having a doping of the second conductivity type and extending from the top surface of the semiconductor substrate to a second depth, which is greater than the halo depth;

removing the dummy deep source region and the dummy deep drain region selective to a portion of the semiconductor region having the doping of the first conductivity type; and

selectively depositing the second semiconductor material directly on the portion of the semiconductor region.

According to another embodiment, the method further comprises:

forming at least one gate spacer on the gate electrode and directly on a portion of the second semiconductor material; and

forming a deep source region and a deep drain region, each of which having a doping of the second conductivity type, by implanting dopants of the second conductivity type into the semiconductor substrate, wherein the deep source region comprises a vertically abutting stack of a top source region comprising the second conductive material and a bottom source region comprising the first conductivity material, and wherein the seep drain region comprises a vertically abutting stack of a top drain region comprising the second conductive material and a bottom drain region comprising the first conductivity material.

According to even another embodiment, the method further comprises:

forming at least one gate spacer on the gate electrode and directly on a portion of the second semiconductor material;

removing a source side recessed region and a drain side recessed region by etching exposed portions of the second semiconductor material, wherein two portions of the second semiconductor material remain directly beneath the gate electrode and the at least one gate spacer; and

selectively depositing the second semiconductor material within the source side recessed region and the drain side recessed region.

According to yet another embodiment, the first semiconductor material is silicon and the second semiconductor material comprises one of silicon germanium alloy, silicon carbon alloy, and silicon germanium carbon alloy.

According to another aspect of the present invention, another method of forming a semiconductor structure is provided, which comprises:

providing a semiconductor region comprising a first semiconductor material and having a doping of a first conductivity type at a first dopant concentration in a semiconductor substrate;

forming a gate electrode containing a gate dielectric and a gate conductor on the semiconductor substrate;

forming a dummy source extension region and a dummy drain extension region by implanting dopants of the first conductivity type into the semiconductor region, wherein each of the dummy source extension region and the dummy drain extension region has a doping of the first conductivity type at a second dopant concentration, extends from a top surface of the semiconductor substrate to an first depth, and abuts a portion of the semiconductor region having the first dopant concentration, wherein the second dopant concentration is greater than the first dopant concentration;

removing the dummy source extension region and the dummy drain extension region selective to the portion of the semiconductor region having the first dopant concentration; and

selectively depositing a second semiconductor material directly on the source side halo region and the drain side halo region, wherein the second semiconductor material is different from the first semiconductor material.

According to one embodiment, the method comprises:

forming a dummy deep source region and a dummy deep drain region, each of which having a doping of the first conductivity type at a third dopant concentration and extending from the top surface of the semiconductor substrate to a second depth, which is greater than the first depth, wherein the third dopant concentration is greater than the first dopant concentration;

removing the dummy deep source region and the dummy deep drain region selective to the portion of the semiconductor region having the doping of the first conductivity type; selectively depositing the second semiconductor material directly on the portion of the semiconductor region; and

forming a source side halo region and a drain side halo region directly beneath two portions of the second semiconductor material.

### BRIEF DESCRIPTION OF THE DRAWINGS

FIGS. 1-9 are sequential vertical cross-sectional views of a first exemplary semiconductor structure according to a first embodiment of the present invention.

FIGS. 10-17 are sequential vertical cross-sectional views of a second exemplary semiconductor structure according to a second embodiment of the present invention.

FIGS. 18-25 are sequential vertical cross-sectional views of a third exemplary semiconductor structure according to a third embodiment of the present invention.

FIGS. 26-31 are sequential vertical cross-sectional views of a fourth exemplary semiconductor structure according to a fourth embodiment of the present invention.

FIG. 32 is a vertical cross-sectional view of a fifth exemplary semiconductor structure according to a fifth embodiment of the present invention.

### DETAILED DESCRIPTION OF THE INVENTION

As stated above, the present invention relates to stressed CMOS devices with embedded stress-inducing material in the source and drain extension regions so that heterojunctions between two semiconductor materials coincide with p-n junctions, and methods of manufacturing the same, which are now described in detail with accompanying figures. It is noted that like and corresponding elements are referred to by like reference numerals.

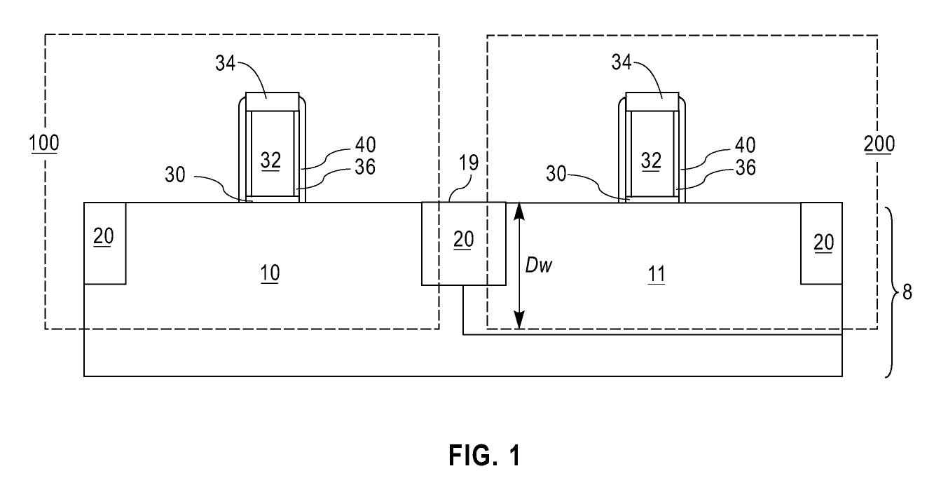

Referring to FIG. 1, a first exemplary semiconductor structure according to a first embodiment of the present invention is shown, which comprises a semiconductor substrate 8 containing a first semiconductor region 10 and shallow trench isolation 20. The first semiconductor region 10 comprises a first semiconductor material having a doping of a first conductivity type at a first dopant concentration. The semiconductor substrate 8 may further contain a second semiconductor region 11 comprising the first semiconductor material and having a doping of a second conductivity type, wherein the second conductivity type is the opposite of the first conductivity type. The first semiconductor region 10 may have a p-type doping and the second semiconductor region 11 may have an n-type doping, or vice versa. Typically, the second semiconductor region 11 comprises a well extending from a top surface 19 of the semiconductor substrate to a well depth Dw into the semiconductor substrate 8.

The first semiconductor material of the first and second semiconductor regions (10, 11) may be selected from, but is not limited to, silicon, germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials. In one case, the first semiconductor material comprises silicon. Preferably, the first and second semiconductor regions (10, 11) are single crystalline, i.e., have the same crystallographic orientations throughout the volume of the semiconductor substrate 8.

The semiconductor substrate 8 may be a bulk substrate, a semiconductor-on-insulator (SOI) substrate, or a hybrid substrate having a bulk portion and an SOI portion. While the present invention is described with a bulk substrate, embodiments employing an SOI substrate or a hybrid substrate are explicitly contemplated herein.

The first semiconductor region 10 and the second semiconductor region 11 are typically lightly doped, i.e., have a dopant concentration from about 1.0×10¹⁵/cm³ to about 3.0×10¹⁸/cm³, and preferably from about 1.0×10¹⁵/cm³ to about 1.0×10¹⁸/cm³, although lesser and greater dopant concentrations are explicitly contemplated herein.

A first device 100 and a second device 200 are formed on the semiconductor substrate 8. A first device 100 may be a metal-oxide-semiconductor field effect transistor (MOSFET) of the second conductivity type, and the second device 200 may be a MOSFET of the first conductivity type. The first device 100 comprises a portion of the first semiconductor region 10 and a first gate electrode formed thereupon. Likewise, the second device comprises a portion of the second semiconductor region 200 and a second gate electrode formed thereupon. Each of the first gate electrode and the second gate electrode comprises a gate dielectric 30, a gate conductor 32, and a gate cap dielectric 34. The gate dielectric 30 may comprise a conventional silicon oxide based gate dielectric material or a high-k gate dielectric material known in the art. The gate conductor 32 may comprise a doped semiconductor material such as doped polysilicon or a doped polycrystalline silicon alloy, or may comprise a metal gate material known in the art. The gate cap dielectric 34 comprises a dielectric material such as a dielectric oxide or a dielectric nitride. For example, the gate cap dielectric may comprise silicon nitride.

In case the gate conductor 32 comprises a semiconductor material that forms an oxide, an optional gate sidewall oxide 36 may be formed by oxidation of the gate conductor 32. For example, the gate conductor 32 may comprise dope polysilicon and the optional gate sidewall oxide 36 may comprise silicon oxide. It is emphasized that the optional gate sidewall oxide 36 may, or may not, be present in the first exemplary semiconductor structure. In case the optional gate sidewall oxide 36 is not present, sidewalls of the gate dielectric 30, sidewalls of the gate conductor 32, and sidewalls of the gate cap dielectric 34 are substantially coincident as seen in a top down view, i.e., as seen from above. A first gate spacer 40 may be formed on the sidewalls of the gate conductor 32, or on the sidewalls of the optional gate sidewall oxide 36, if present. The first gate spacer 40 comprises a dielectric material such as a dielectric oxide or a dielectric nitride. For example, the first gate spacer 40 may comprise a CVD silicon oxide, i.e., a silicon oxide formed by chemical vapor deposition (CVD). The thickness of the first gate spacer 40 is an offset distance for optimized overlap of source and drain extension region to be subsequently formed. The first gate spacer 40 has a thickness from about 3 nm to about 30 nm, and typically from about 5 nm to about 20 nm, although lesser and greater thicknesses are contemplated herein also.

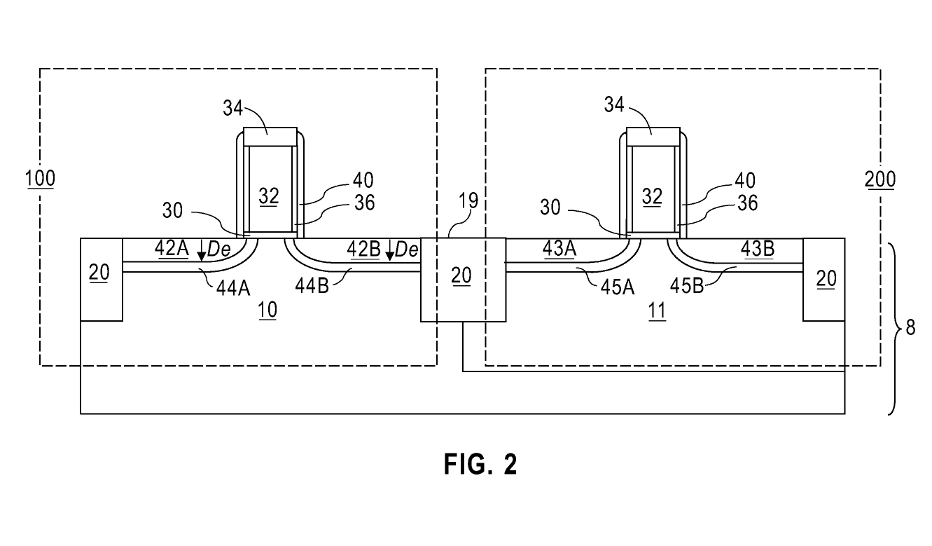

Referring to FIG. 2, masked ion implantations are sequentially performed into the first semiconductor region 10 and the second semiconductor region 11 employing block level masks (not shown). Specifically, a first photoresist (not shown) is applied on the semiconductor substrate 8 and lithographically patterned with a first block mask such that the first device 100 is exposed and the second device 200 is covered by the first photoresist. A dummy first source extension region 42A and a dummy first drain extension region 42B extending from the top surface 19 of the semiconductor substrate 8 to an extension depth De are formed in the first device 100 by ion implantation of dopants of a second conductivity type, which is the opposite of the first dopant conductivity type. Thus, the dummy first source extension region 42A and the dummy first drain extension region 42B have a doping of the second conductivity type. The dopant concentration of the dummy first source extension region 42A and the dummy second drain extension region 42B may be from about 3.0×10¹⁸/cm³ to about 3.0×10²¹/cm³, and typically from about 3.0×10¹⁹/cm³ to about 1.0×10²¹/cm³, although lesser and greater dopant concentrations are herein contemplated also. Preferably, the dose of the ion implantation is set at a high enough level to amorphize the implanted region. Each of the dummy first source extension region 42A and the dummy first drain extension region 42B abut an edge portion of a bottom surface of the gate dielectric 36 in the first device 100.

A first source side halo region 44A and a first drain side halo region 44B are formed directly beneath the dummy first source extension region 42A or the dummy first drain extension region 42B by an angled ion implantation of dopants of the first conductivity type employing the same first photoresist. Thus, the first source side halo region 44A and the first drain side halo region 44B have a doping of the first conductivity type. The dopant concentration of the first source side halo region 44A and the first drain side halo region 44B is herein referred to as a second dopant concentration, and may be from about 3.0×10¹⁷/cm³ to about 3.0×10²⁰/cm³, and typically from about 3.0×10¹⁸/cm³ to about 3.0×10¹⁹/cm³, although lesser and greater dopant concentrations are herein contemplated also. The second dopant concentration is greater than the first dopant concentration, which is the dopant concentration of the first semiconductor region 10. Each of the first source side halo region 44A and a first drain side halo region 44B abut a portion of the gate dielectric 40. The order of the ion implantation for formation of the dummy source and drain extension regions (42A, 42B) and the ion implantation for formation of the first source and drain side halo regions (44A, 44B) may be reversed to form the same structures. The angles of both ion implantations may be adjusted as needed. The first photoresist is subsequently removed.

A second photoresist (not shown) is applied and patterned with a second block mask so that the first device 100 is covered with the second photoresist, while the second device 200 is exposed. Dopants of the first conductivity type are implanted into the second semiconductor region 11 to form a second source extension region 43A and a second drain extension region 43B. The dopant concentration of the second source extension region 43A and the second drain extension region 43B may be from about 3.0×10¹⁸/cm³ to about 3.0×10²⁰/cm³, and typically from about 3.0×10¹⁹/cm³ to about 1.0×10²¹/cm³, although lesser and greater dopant concentrations are herein contemplated also. Further, dopants of the second conductivity type are implanted into the second semiconductor region to a greater depth than bottom surfaces of the second source extension region 43A and the second drain extension region 43B to form a second source side halo region 45A and a second drain side halo region 45B. The dopant concentration of the second source side halo region 45A and the second drain side halo region 45B may be from about 3.0×10¹⁷/cm³ to about 3.0×10²⁰/cm³, and typically from about 3.0×10¹⁸/cm³ to about 3.0×10¹⁹/cm³, although lesser and greater dopant concentrations are herein contemplated also.

As is well known in the art, lateral straggle of implanted ions is greater near the surface into which ion implantation is performed than at the projected range of the ion implantation, which is the depth of the implanted region. Consequently, each of the dummy source and drain extension regions (42A, 42B) abut one of the first source and drain side halo regions (44A, 44B) at a convexly arced surface extending from the gate dielectric 30 to the extension depth De into the semiconductor substrate.

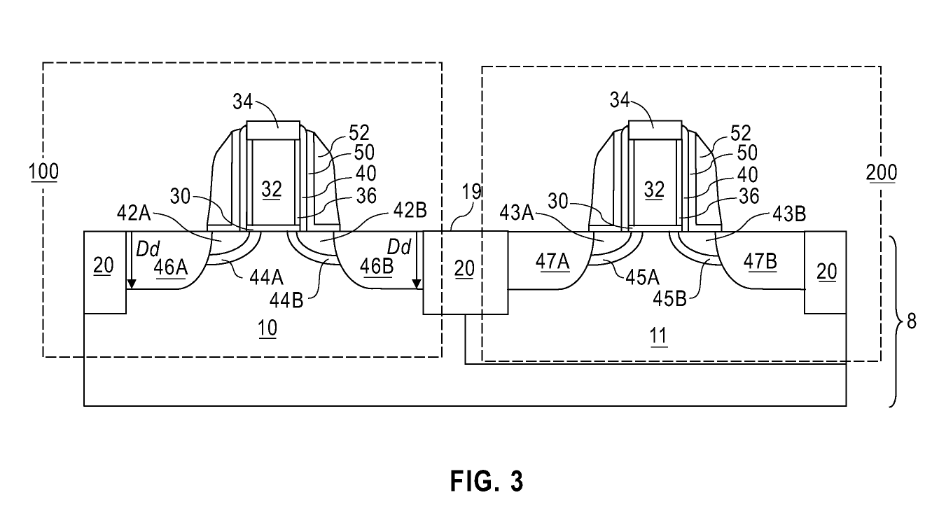

Referring to FIG. 3, a second gate spacer 50 and a third gate spacer 52 are deposited on the gate electrode in each of the first device 100 and the second device 200. The second gate spacer 50 and the third gate spacer 52 comprise a dielectric material, such as a dielectric oxide or a dielectric nitride. For example, the second gate spacer 50 may comprise silicon oxide, and the third gate spacer 52 may comprise silicon nitride. The lateral thickness of the combination of the second gate spacer 50 and the third gate spacer 52 may be from about 15 nm to about 100 nm, and typically from about 30 nm to about 80 nm, while lesser and greater thicknesses are explicitly contemplated herein also. It is well known in the art that a different number of gate spacer(s) may be employed to optimize the performance of semiconductor devices. Thus, the first gate spacer 40, the second gate spacer 50, and the third gate spacer 52 are herein collectively called “at least one gate spacer” to connote a variability in the number of gate spacers employed in the first exemplary semiconductor structure.

Masked ion implantations are sequentially performed to form deep source and drain regions in the first device 100 and the second device 200. Specifically, a third photoresist (not shown) is applied on the semiconductor substrate 8 and lithographically patterned with a third block mask such that the first device 100 is exposed and the second device 200 is covered by the third photoresist. Optionally, the third block mask may be the same as the first block mask. A dummy first deep source region 46A and a dummy first deep drain region 46B extending from the top surface 19 of the semiconductor substrate 8 to a deep source and drain depth Dd are formed in the first device 100 by ion implantation of dopants of the second conductivity type. The dummy first deep source and drain regions (46A, 46B) comprise the regions into which a substantial amount of dopants of the second conductivity type are implanted. Thus, the dummy first deep source region 46A and the dummy first deep drain region 46B have a doping of the second conductivity type. The dopant concentration of the dummy first deep source region 46A and the dummy deep second drain region 46B may be from about 3.0×10¹⁸/cm³ to about 3.0×10²¹/cm³, and typically from about 3.0×10¹⁹/cm³ to about 1.0×10²¹/cm³, although lesser an greater dopant concentrations are herein contemplated also. The dose of the ion implantation at this step is high enough to reverse the doping type of the portion of the first source side halo region 44A and the first drain side halo region 44B. The entirety of the implanted regions during this ion implantation step has the second conductivity type doping. Preferably, the dose of the ion implantation is set at a high enough level to amorphize the implanted region.

A fourth photoresist (not shown) is applied and patterned with a fourth block mask so that the first device 100 is covered with the fourth photoresist, while the second device 200 is exposed. Optionally, the fourth block mask may be the same as the second block mask. Dopants of the first conductivity type are implanted into the second device 200 to form a second deep source region 47A and a second deep drain region 47B. Dopant concentration of the second deep source region 47A and the second deep drain region 47B may be from about 3.0×10¹⁸/cm³ to about 3.0×10²¹/cm³, and typically from about 3.0×10¹⁹/cm³ to about 1.0×10²¹/cm³, although lesser and greater dopant concentrations are herein contemplated also.

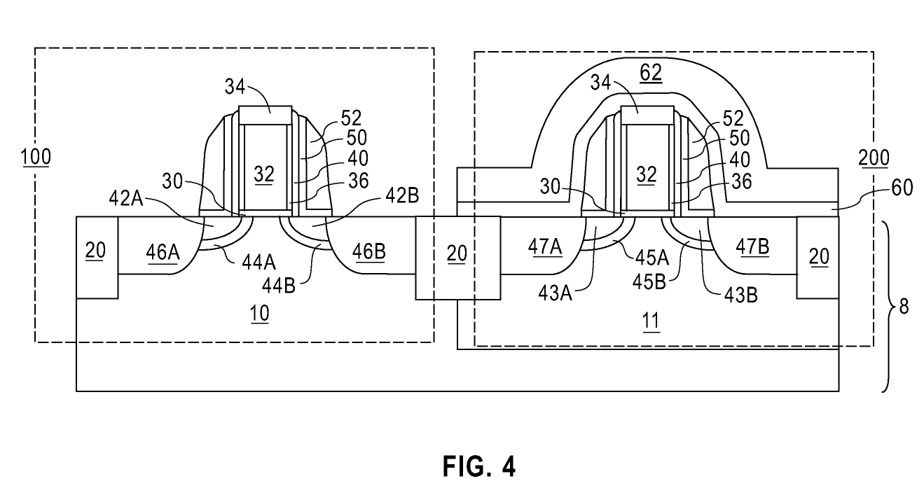

Referring to FIG. 4, at least one mask layer is formed on the second device 200, while the first device 100 is exposed. The at least one mask layer may comprise a stack of a first mask layer 60 and a second mask layer 62. The stack of the first mask layer 60 and the second mask layer 62 may be formed by blanket depositions, followed by lithographic patterning and etching of the mask layers (60, 62) so that a portion of the mask layers (60, 62) remains on the second device 200, while the first device 100 is exposed after the etching. The first mask layer 60 and the second mask layer 62 may comprise dielectric materials. For example, the first mask layer 60 may comprise silicon oxide having a thickness from about 3 nm to about 30 nm, and the second dielectric layer may comprise silicon nitride having a thickness from about 5 nm to about 200 nm, although lesser and greater thicknesses are also contemplated herein. The surfaces of the at least one mask layer do not provide a growth template during a subsequent selective epitaxy of a second semiconductor material. A different number of mask layer(s) as well as different materials for each of the at least one mask layer may be employed to practice the present invention.

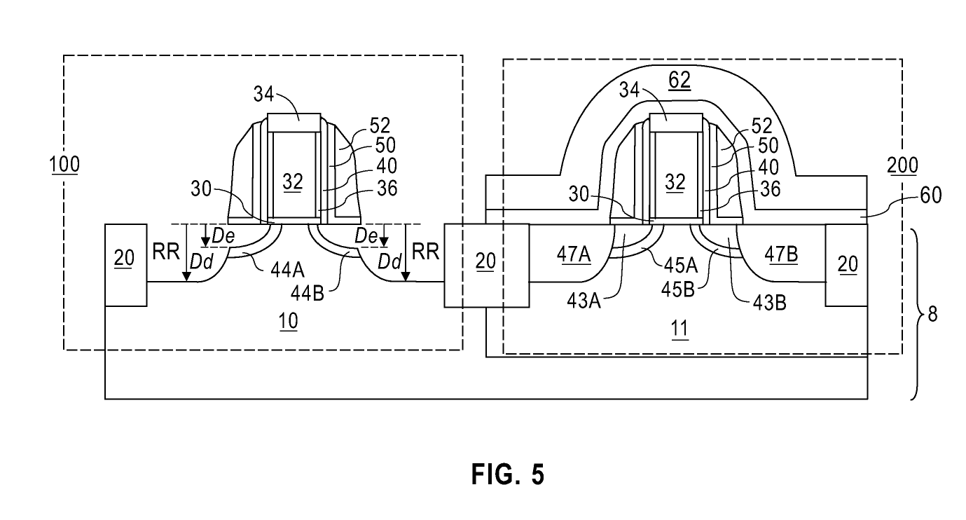

Referring to FIG. 5, the dummy first source extension region 42A, the dummy first drain extension region 42B, the dummy first deep source region 46A, and the dummy first deep drain region 46B are removed selective to the first source side halo region 44A, the first drain side halo region 44B, and the first semiconductor region 10 by a conductivity dependent etch or a dopant concentration dependent etch.

The conductivity dependent etch may be a wet etch or a dry etch including a reactive ion etch. The conductivity dependent etch selectively removes regions containing the first semiconductor material having the second conductivity type doping relative to the first semiconductor material having the first conductivity type doping.

In one exemplary case, the first semiconductor material may comprise silicon, the first conductivity type may be p-type, the second conductivity type may be n-type, and the conductivity type dependent etch may be a wet etch employing an ammonium hydroxide NH₄OH) or a tetramethyl-ammonium hydroxide (TMAH; (CH₃)₄NOH) based chemistry. Such a wet etch selectively removes n-type doped silicon selective to p-type doped silicon. Since ammonium hydroxide and TMAH etches are known to have crystallographic orientation dependent, the dummy first source and drain extension regions (42A, 42B) and the dummy deep source and drain regions (46A, 463) that is amorphized during the ion implantation steps remain amorphous until they are removed by the conductivity type dependent etch by postponing thermal activation of implanted dopants, which may cause recrystallization of the amorphized regions. In one case, an activation anneal may be performed after the conductivity type dependent etch and prior to selective epitaxy of a second semiconductor material to minimize thermal diffusion of dopants after the selective epitaxy.

In another exemplary case, the first semiconductor material may comprise silicon, the first conductivity type may be p-type, the second conductivity type may be n-type, and the conductivity type dependent etch may be an SF₆ and/or HBr based reactive ion etch or a chemical dry etching (CDE). Such a dry etch selectively removes n-type doped silicon selective to p-type doped silicon.

The dopant concentration dependent etch removes the first semiconductor material having a high dopant concentration, selective to the first semiconductor material having a low dopant concentration. The distinction between the high dopant concentration and the low dopant concentration is relative and depends on the etch chemistry. Typically, a dopant concentration between about 3.0×10¹⁷/cm³ and about 1.0×10¹⁹/cm³ is considered a boundary dopant concentration between the low dopant concentration and the high dopant concentration. In case the dopant concentration of the first source side halo region 44A and the first drain side halo region 44B is less than the boundary dopant concentration, a dopant concentration dependent etch may be employed to remove the dummy first source and drain extension regions (42A, 42B) and the dummy deep source and drain regions (46A, 46B) selective to the first source and drain side halo regions (44A 44B) and the first semiconductor region 10.

In one exemplary case, the first semiconductor material may comprise silicon, the boundary dopant concentration may be 1.0×10¹⁸/cm³, the first source and drain side halo regions (44A 44B) and the first semiconductor region 10 have dopant concentrations less than 1.0×10¹⁸/cm³, and the dopant concentration dependent etch may be a wet etch employing hydrofluoric nitric acetate solution, or “HNA” (HF:HNO₃:CH₃COOH or H₂O). In this chemistry, CH₃COOH or H₂O is a diluent.

The conductivity type dependent etch or the dopant concentration dependent etch forms recessed regions RR in the first device 100 such that the exposed surfaces are coincident with the boundaries between the collective set of the first semiconductor region 10, the first source side halo region 44A, and the first drain side halo region 44B, and the collective set of the dummy first source and drain extension regions (42A, 42B) and the dummy deep source and drain regions (46A, 46B).

The exposed surfaces one of the first source and drain side halo regions (44A, 44B), which extends from the gate dielectric 30 to the extension depth De into the semiconductor substrate, are convexly arced. Preferably, the convexly arced surface is free of crystallographic facets by employing an etch process in which the etch rate is determined primarily be dopant concentration and/or dopant conductivity type.

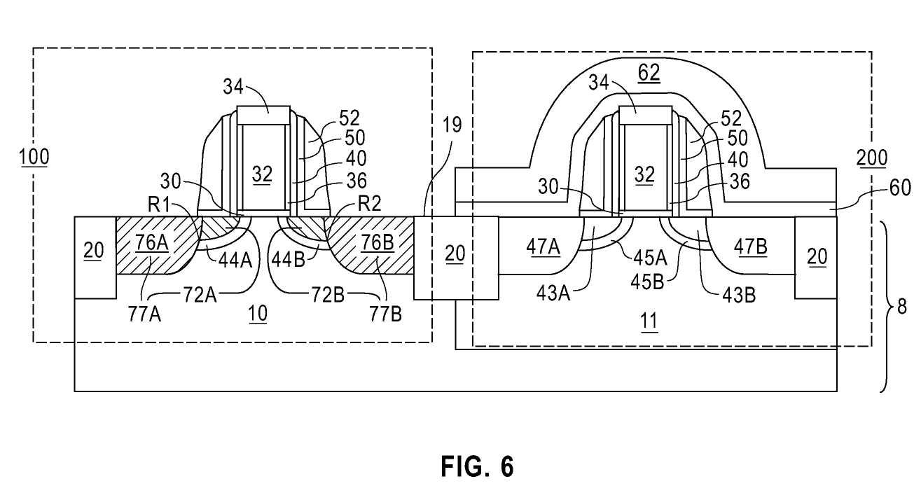

Referring to FIG. 6, a second semiconductor material is grown by selective epitaxy in the recessed regions RR. The second semiconductor material is a different material from the first semiconductor material. Preferably, the second semiconductor material has a lattice constant that is matched to the lattice constant of the first semiconductor material within about 6%, and preferably within about 2%, to enable epitaxial growth of the second semiconductor material on the first semiconductor material without generating an excessive level of crystalline defect density. Not necessarily but preferably, the second semiconductor material has the same lattice structure as the first semiconductor material. In one example, the first semiconductor material is silicon and the second semiconductor material is one of silicon germanium alloy (SiGe), silicon carbon alloy (Si:C), or a silicon carbon germanium alloy. In another example, the first semiconductor material may be gallium arsenide and the second semiconductor material may be a gallium arsenide compound with at least another element.

During the selective epitaxy, the second semiconductor material is deposited on exposed semiconductor surfaces, while no deposition occurs on insulator surfaces, i.e., the growth of the second semiconductor material is selective to insulator surfaces. The exposed semiconductor surfaces comprise the surfaces of the first semiconductor region 10, the source side halo region 44A, and the drain side halo region 44B. The second semiconductor material that is epitaxially grown in the recessed regions RR constitutes a first source extension region 72A, a first drain extension region 72B, a first deep source region 76A, and a first deep drain region 76B. The first source extension region 72A and the first deep source region 76A are integrally formed, i.e., formed as one piece. Likewise, the first drain extension region 72B and the first deep drain region 76B are also integrally formed. A first ridge R1 located at the extension depth De (See FIG. 5), and perpendicular to the plane of FIG. 6, and at which two of the outer surfaces of the first source side halo region 44A meet at an angle, constitutes a first boundary line between the first source extension region 72A and the first deep source region 76A. Likewise, a second ridge R2 located at the extension depth De (See FIG. 5), and perpendicular to the plane of FIG. 6, and at which two of the outer surfaces of the first drain side halo region 44B meet at an angle, constitutes a second boundary line between the first drain extension region 72B and the first deep drain region 76B. Vertical surfaces extending upward from the two ridges (R1, R2) constitute a boundary surface between the first source extension region 42A and the first deep source region 76A and another boundary between the first drain extension region 4213 and the first deep drain region 76B. The boundary surfaces do not have physical manifestation due to the integral formation of two regions across each of the boundary surfaces, but is employed for the description of the present invention to emphasize a physical feature of lateral protrusion of the first source extension region 72A and the first drain extension region 72B from the first deep source region and the first deep drain region, respectively.

Heterojunctions that are formed at the boundary of the first semiconductor material and the second semiconductor material coincide with, or are located in close proximity to and in self-alignment to, p-n junctions between p-doped semiconductor regions and n-doped semiconductor regions. Thus, the boundary between the collective set of the first semiconductor region 10, the first source side halo region 44A, and the first drain side halo region 44B, and the collective set of the first source extension region 72A, the first drain extension region 72B, the first deep source region 76A, and the first deep drain region 76B is both a heterojunction of two different materials and a p-n junction between semiconductor materials of two different conductivity types. Use of in-situ doping has an additional advantage of minimizing thermal diffusion of dopants by obviating the need for a dopant activation anneal since the dopants introduced into the second semiconductor material during the in-situ doping are incorporated into substitutional sites of the lattice structure.

While the present invention is described with the first deep source region 76A and the first deep drain region 76B that have top surfaces that are substantially coplanar with the remainder of the top surfaces 19 of the semiconductor substrate 8, it is known in the art that the first deep source region 76A and the first deep drain region 76B may be raised above the remainder of the top surfaces 19 of the semiconductor substrate. Such variations are explicitly contemplated herein.

Preferably, each of the first source and drain extension regions (72A, 72B) abut one of the first source and drain side halo regions (44A, 44B) at a convexly arced surface extending from the gate dielectric 30 to the extension depth De into the semiconductor substrate, which is the exposed surface of the first source and drain side halo regions (44A, 44B) prior to formation of the first source and drain extension regions (72A, 72B) and the first deep source and drain regions (76A, 76B). The convexly arced surface is free of crystallographic facets due to the dopant concentration dependency and/or dopant conductivity type dependency of the etch process and an inherent curvature of the lateral edge of implanted regions.

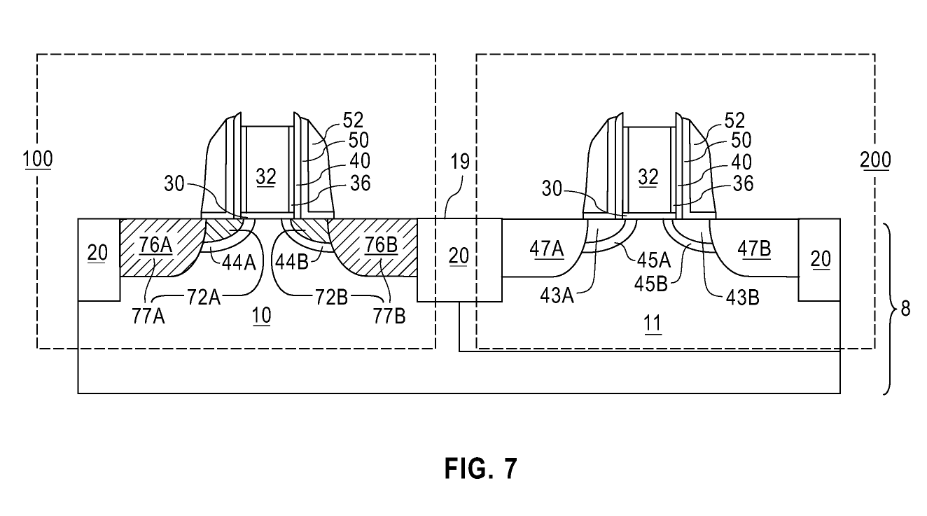

Referring to FIG. 7, the at least one mask layer (60, 62) are removed by an etch such as a wet etch or a reactive ion etch. Further, the gate cap dielectric 34 is also removed by another etch from the first device 100 and the second device 200. The gate conductor 32 in each of the first device 100 and the second device 200 is exposed.

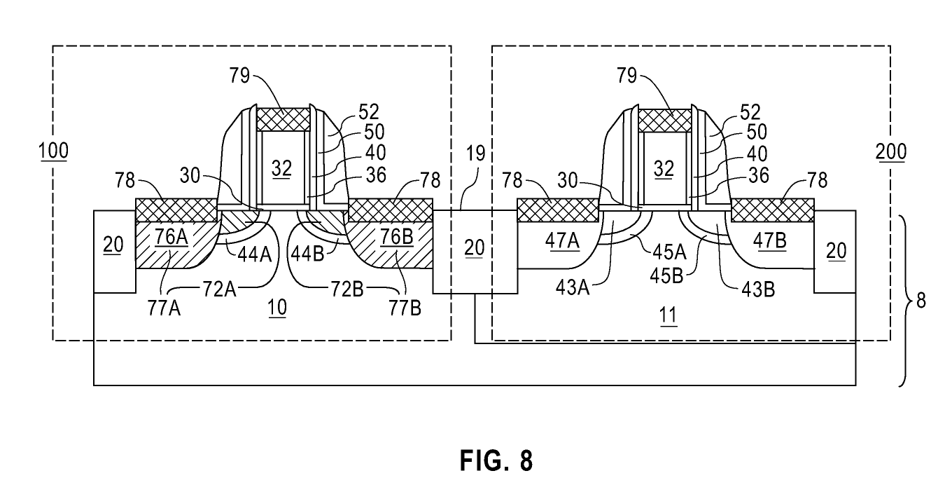

Referring to FIG. 8, metal semiconductor alloys are formed on exposed semiconductor surfaces by deposition of a metal layer (not shown) followed by anneal that induces reaction of the metal layer with the underlying semiconductor material. Specifically, source and drain metal semiconductor alloys 78 are formed on the first deep source region 76A, the first deep drain region 76B, the second deep source region 47A, and the second deep drain region 47B. Gate metal semiconductor alloys 79 are formed on the gate conductor 32 in each of the first device 100 and the second device 200. In case the second semiconductor material comprises a silicon alloy such as a silicon germanium alloy or a silicon carbon alloy, the source and drain metal semiconductor alloys 78 comprise a silicide alloy such as a silicide germanide alloy or a silicide carbon alloy. Methods of forming the various metal semiconductor alloys (78, 79) are known in the art.

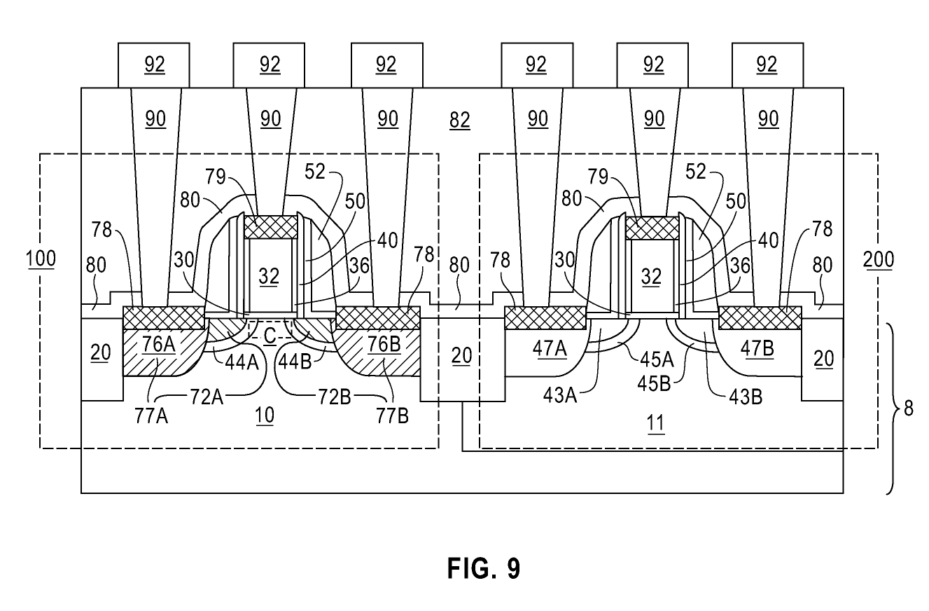

Referring to FIG. 9, a mobile ion diffusion barrier layer 80 is deposited over the exemplary structure. The mobile ion diffusion barrier layer 80 may comprise silicon nitride. The thickness of the mobile ion diffusion barrier layer 80 is from about 10 nm to about 80 nm. A middle-of-line (MOL) dielectric layer 82 is deposited over the mobile ion diffusion barrier layer 80. The MOL dielectric layer 82 may comprise, for example, a CVD oxide. The CVD oxide may be an undoped silicate glass (USG), borosilicate glass (BSG), phosphosilicate glass (PSG), fluorosilicate glass (FSG), borophosphosilicate glass (BPSG), or a combination thereof The thickness of the MOL dielectric layer 82 may be from about 200 nm to about 500 nm. The MOL dielectric layer 82 is preferably planarized, for example, by chemical mechanical polishing (CMP).

Various contact via holes are formed in the MOL dielectric layer 82 and filled with metal to from various contact vias 90. Specifically, contact vias 90 are formed on the gate metal semiconductor alloys 79 and on the source and drain metal semiconductor alloys 72. A first level metal wiring 92 is thereafter formed followed by further formation of back-end-off-line (BEOL) structures.

The second semiconductor material applies a uniaxial stress in the channel region C of the first device 100 such that mobility of charge carriers is enhanced due to the uniaxial stress. In case the first semiconductor material comprises silicon, the first device 100 may be a p-type MOSFET, the second semiconductor material may be a silicon germanium alloy, and the uniaxial stress may be a compressive stress so that hole mobility is enhanced due to the compressive uniaxial stress. In case the first semiconductor material comprises silicon, the first device 100 may be an n-type MOSFET, the second semiconductor material may be a silicon carbon alloy, and the uniaxial stress may be a tensile stress so that electron mobility is enhanced due to the tensile uniaxial stress.

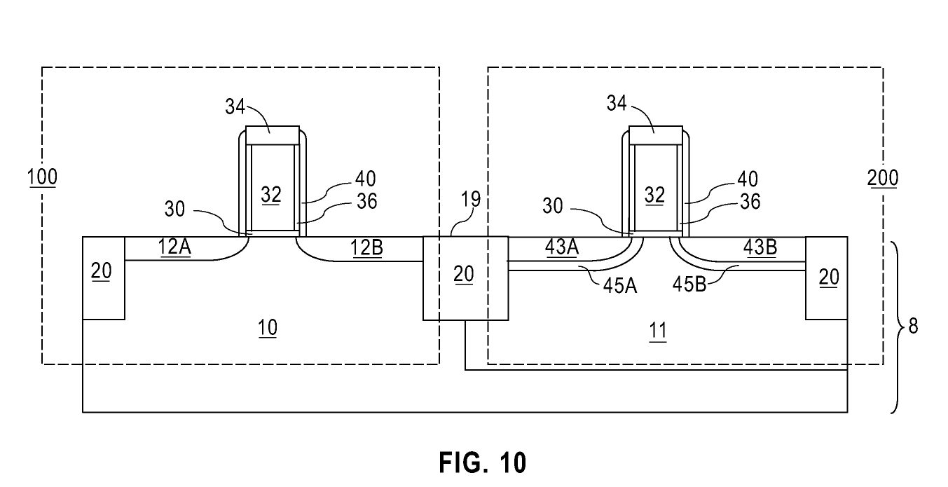

Referring to FIG. 10, a second exemplary semiconductor structure according to a second embodiment of the present invention is derived from the first exemplary structure in FIG. 1. A dummy first source extension region 12A, a dummy first drain extension region 12B, a second source extension region 43A, and a second drain extension region are formed in the semiconductor substrate 8 by ion implantation of dopants of the first conductivity type. Thus, the first semiconductor region 10, the dummy first source extension region 12A, and the dummy first drain extension region 12B have the first conductivity type doping. The dopant concentration of the dummy first source extension region 12A and the dummy first drain extension region 12B is substantially higher than the first dopant concentration. The dopant concentration of the dummy first source extension region 12A and the dummy second drain extension region 12B may be from about 3.0×10¹⁸/cm³ to about 3.0×10²¹/cm³, and typically from about 3.0×10¹⁹/cm³ to about 1.0×10²¹/cm³, although lesser and greater dopant concentrations are herein contemplated also. The first dopant concentration may be from about 1.0×10¹⁵/cm³ to about 3.0×10¹⁸/cm³, and preferably from about 1.0×10¹⁵/cm³ to about 1.0×10¹⁸/cm³, although lesser and greater dopant concentrations are explicitly contemplated herein.

A second source side halo region 45A and a second drain side halo region 4513 having a doping of the second conductivity type are formed as in the first embodiment employing the second block mask.

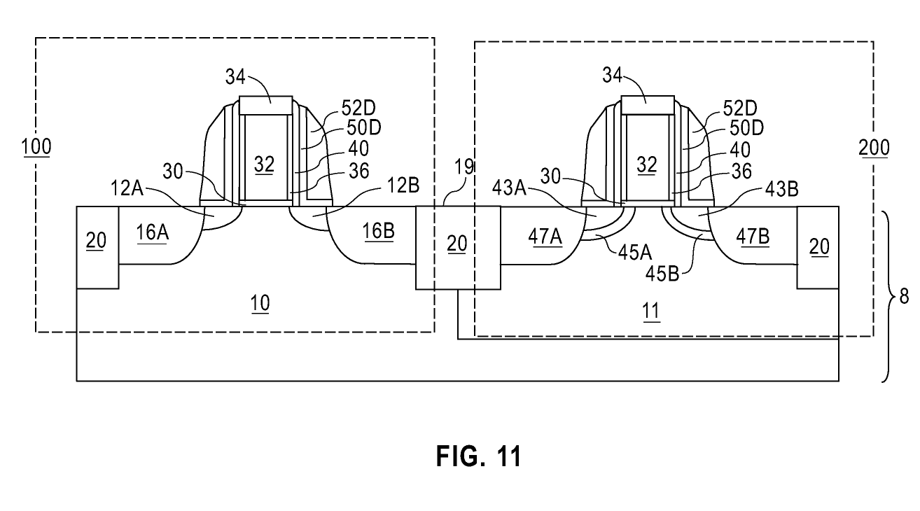

Referring to FIG. 11, a dummy second gate spacer 50D and a dummy third gate spacer 52D are formed on the first device 100 and the second device 20. The dummy second gate spacer 50D may have the same structure and composition as the second gate spacer 50 in the first embodiment. Also, the dummy third gate spacer 52D may have the same structure and composition as the third gate spacer 52 in the first embodiment.

Dopants of the first conductivity type are implanted into the exposed portions of the first semiconductor region 10 and the second semiconductor region 11 to form a dummy first deep source region 16A, a dummy first deep drain region 16B, a second deep source region 47A, and a second deep drain region 47B. Thus, the first semiconductor region 10, the dummy first source extension region 12A, the dummy first drain extension region 12B, the dummy deep source region 16A, and the dummy deep drain region 16B have the first conductivity type doping. The dopant concentration of the dummy first source extension region 12A and the dummy first drain extension region 12B is substantially higher than the first dopant concentration, and is herein referred to as a third dopant concentration. The third dopant concentration may be from about 3.0×10¹⁸/cm³ to about 3.0×10²¹/cm³, and typically from about 3.0×10¹⁹/cm³ to about 1.0×10²¹/cm³, although lesser and greater dopant concentrations are herein contemplated also.

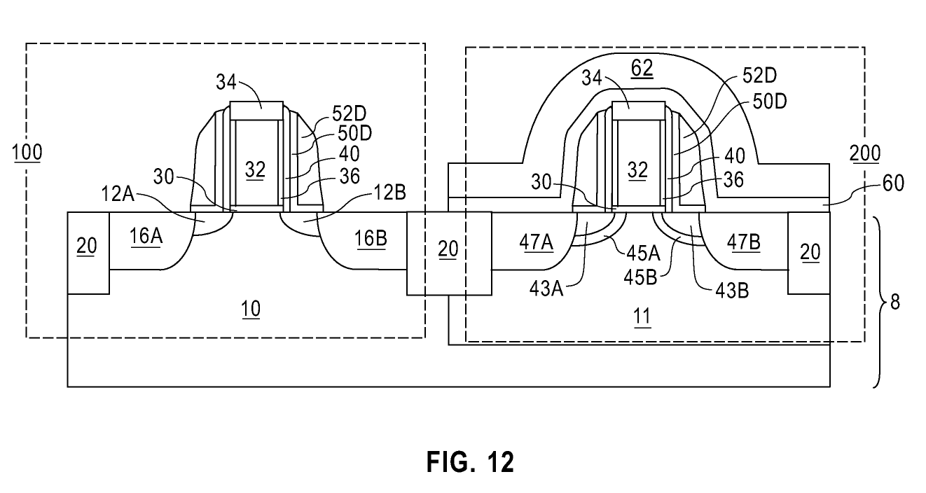

Referring to FIG. 12, at least one mask layer is formed on the second device 200, while the first device 100 is exposed as in the first embodiment. The structure and composition of the at least one mask layer is the same as in the first embodiment.

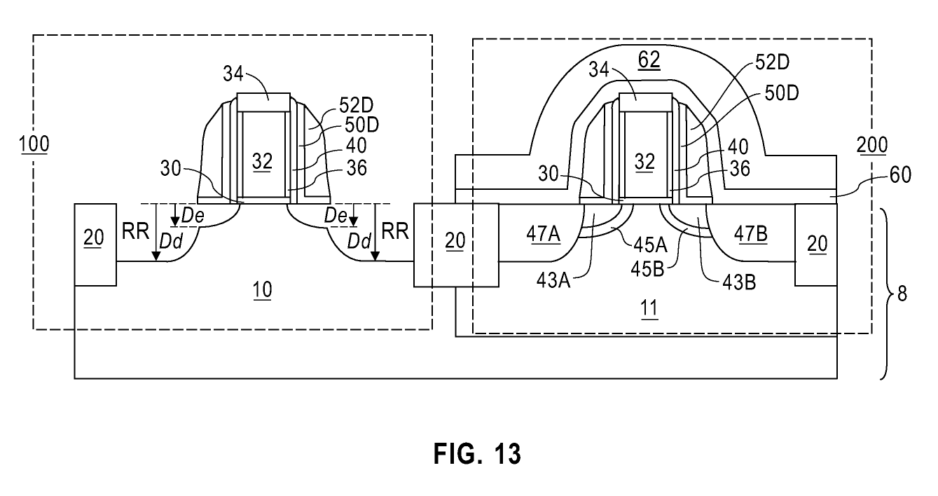

Referring to FIG. 13, the dummy first source extension region 12A, the dummy first drain extension region 12B, the dummy first deep source region 16A, and the dummy first deep drain region 16B are removed selective to the first source side halo region 44A, the first drain side halo region 44B, and the first semiconductor region 10 by a dopant concentration dependent etch.

The dopant concentration dependent etch removes the first semiconductor material having a high dopant concentration, selective to the first semiconductor material having a low dopant concentration. The distinction between the high dopant concentration and the low dopant concentration is relative and depends on the etch chemistry. Typically, a dopant concentration between about 3.0×10¹⁷/cm³ and about 1.0×10¹⁹/cm³ is considered a boundary dopant concentration between the low dopant concentration and the high dopant concentration. In case the dopant concentration of the first source side halo region 44A and the first drain side halo region 44B is less than the boundary dopant concentration, a dopant concentration dependent etch may be employed to remove the dummy first source and drain extension regions (12A, 12B) and the dummy deep source and drain regions (16A, 16B) selective to the first source and drain side halo regions (44A, 44B) and the first semiconductor region 10.

In one exemplary case, the first semiconductor material may comprise silicon, the boundary dopant concentration may be 1.0×10¹⁸/cm³, and the dopant concentration dependent etch may be a wet etch employing hydrofluoric nitric acetate solution, or “HNA” (HF:HNO₃:CH₃COOH or H₂O). In this chemistry, CH₃COOH or H₂O is a diluent. The first source and drain side halo regions (44A 44B) and the first semiconductor region 10 have dopant concentrations less than 1.0×10¹⁸/cm³.

The dopant concentration dependent etch forms recessed regions RR in the first device 100 such that the exposed surfaces are coincident with the boundaries between the collective set of the first semiconductor region 0, the first source side halo region 44A, and the first drain side halo region 44B, and the collective set of the dummy first source and drain extension regions (12A, 12B) and the dummy deep source and drain regions (16A, 16B). The recessed regions RR within the first device 100 have identical structural features, e.g., the extension depth De and the deep source and drain depth Dd, as the recessed regions RR shown in FIG. 5 in the first embodiment.

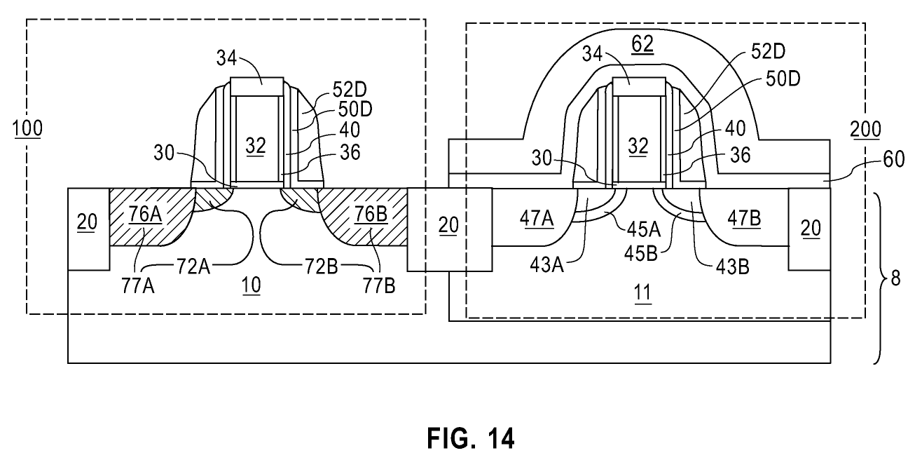

Referring to FIG. 14, a second semiconductor material is grown by selective epitaxy in the recessed regions RR employing the same processing step as in the first embodiment. The structure and composition of the epitaxially grown second semiconductor material are the same as in the first embodiment. The boundary between the collective set of the first semiconductor region 10, the first source side halo region 44A, and the first drain side halo region 44B, and the collective set of the first source extension region 72A, the first drain extension region 72B, the first deep source region 76A, and the first deep drain region 76B is a heterojunction of two different materials and is located in close proximity to and self-aligned to a p-n junction between semiconductor materials of two different conductivity types as in the first embodiment.

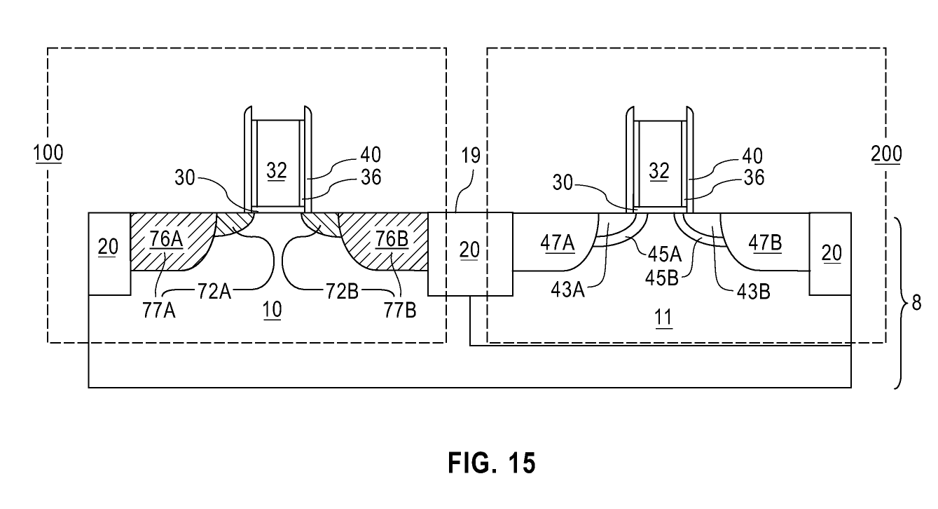

Referring to FIG. 15, the at least one mask layer (60, 62) are removed by an etch such as a wet etch or a reactive ion etch. Further, the second dummy gate spacer 50, the third dummy gate spacer 52, and the gate cap dielectrics 34 are also removed by another etch.

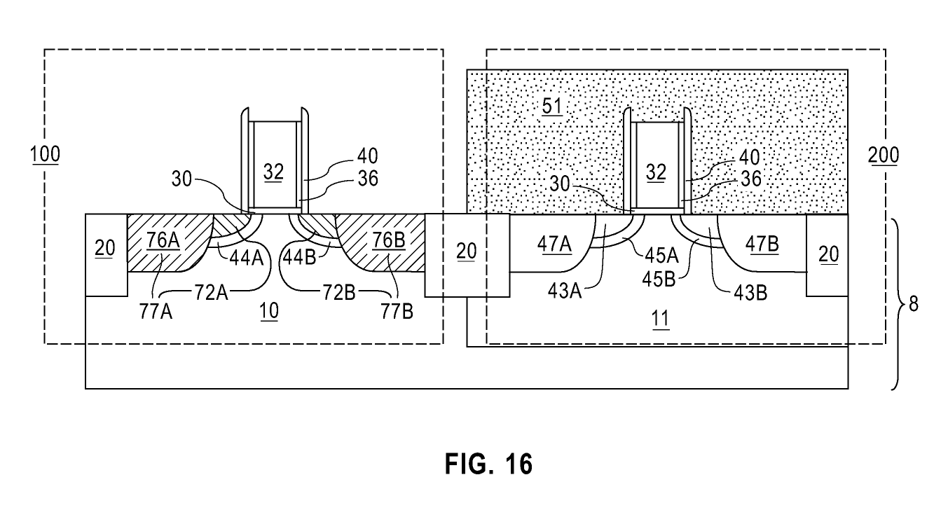

Referring to FIG. 16, a photoresist 51 is applied over the semiconductor substrate 8 and lithographically patterned to cover the second device 200 and expose the first device 100. Dopants of the second conductivity type are implanted into the first device to form a first source side halo region 44A and a drain side halo region 44B. As in the first embodiment, the dopant concentration of the first source side halo region 44A and the first drain side halo region 44B is herein referred to as a second dopant concentration, and may be from about 3.0×10¹⁷/cm³ to about 3.0×10²⁰/cm³, and typically from about 3.0×10¹⁸/cm³ to about 3.0×10¹⁹/cm³, although lesser and greater dopant concentrations are herein contemplated also. The photoresist 51 is subsequently removed.

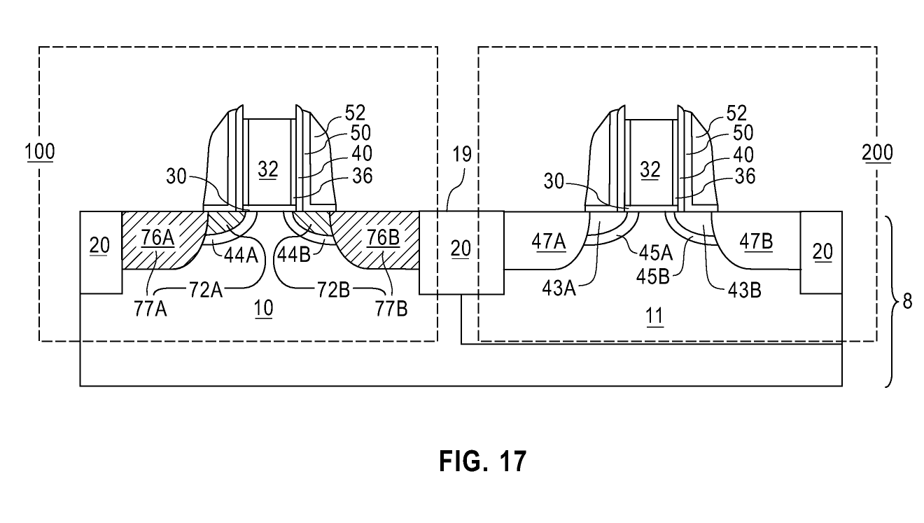

Referring to FIG. 17, a second gate spacer 50 and the third gate spacer 52 may be formed on the gate electrode (30, 32) of each of the first device 100 and the second device 200. The second gate spacer 50 and the third gate spacer 52 may comprise the same material and have the same thickness as in the first embodiment. The lateral thickness of the combination of the second gate spacer 50 and the third gate spacer 52 is determined by a desired offset between the sidewalls of the gate conductor 32 and metal semiconductor alloys to be subsequently formed on the semiconductor substrate 8.

Processing steps shown in FIGS. 8 and 9 may be subsequently employed to provide metal semiconductor alloy regions and contacts as in the first embodiment.

As in the first embodiment, the second semiconductor material applies a uniaxial stress in the channel region of the first device 100 such that mobility of charge carriers is enhanced due to the uniaxial stress.

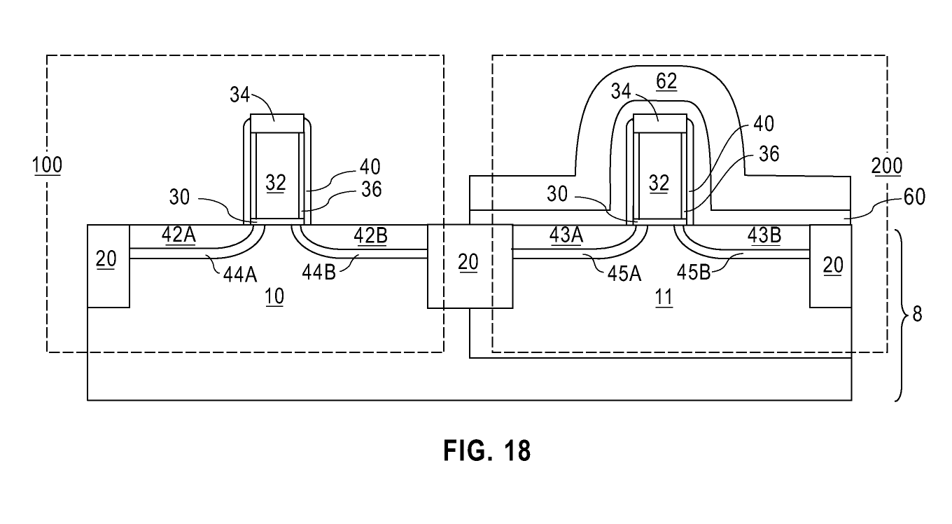

Referring to FIG. 18, a third exemplary semiconductor structure according to a third embodiment of the present invention is derived from the second exemplary semiconductor structure of FIG. 2 by forming at least one mask layer on the second device 200, while exposing the first device 100. The at least one mask layer of the third embodiment may have the same structure and comprise the same material as the at least one mask layer of the first embodiment shown in FIG. 4.

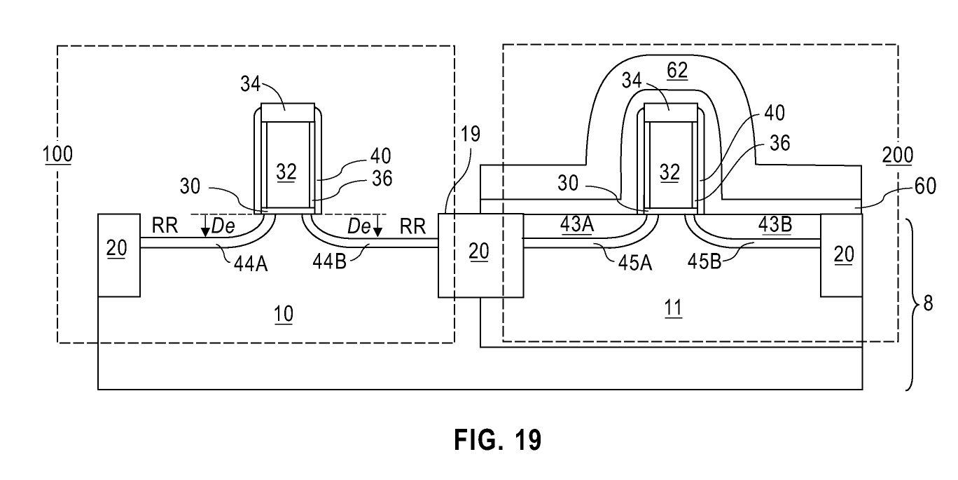

Referring to FIG. 19, the dummy first source extension region 42A and the dummy first drain extension region 42B are removed by a conductivity type dependent etch or a dopant concentration dependent etch described above selective to the first source side halo region 44A and the drain side halo region 44B. Recessed regions formed in the first device 100 extend from a top surface 19 of the semiconductor substrate 8 to an extension depth De, which may be the same as the extension depth De of the first embodiment.

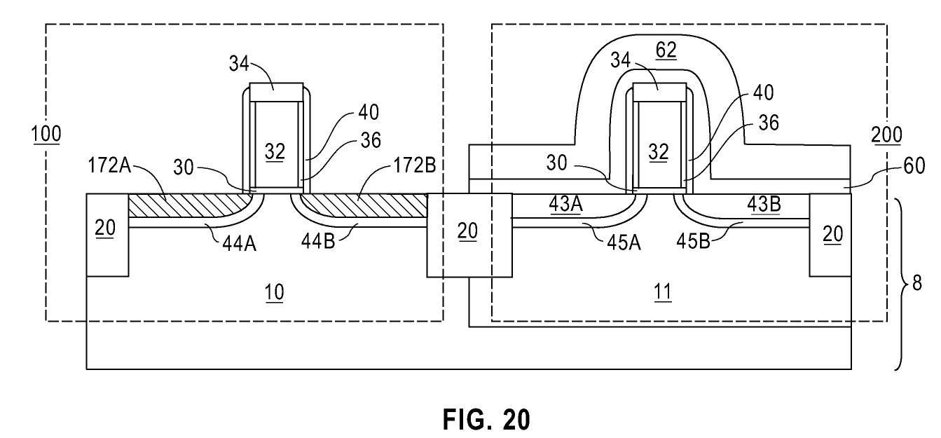

Referring to FIG. 20, a second semiconductor material is selectively deposited in the recessed regions RR to form a first source extension region 172A and a first drain extension region 172B. The same selective epitaxy process employing the same second semiconductor material may be employed as in the first embodiment. Further, the selective epitaxy process may be in-situ doped with dopants of the second conductivity type. The dopant concentration of the first source extension region 172A and the first drain extension region 172B may be from about 3.0×10¹⁸/cm³ to about 3.0×10²¹/cm³, and typically from about 3.0×10¹⁹/cm³ to about 1.0×10²¹/cm³, although lesser and greater dopant concentrations are herein contemplated also. Heterojunctions and p-n junctions are formed coincidently at, or in close proximity to and in self-alignment to, the interface between the first source side halo region 44A and the first source extension region 172A and the interface between the drain side halo region 44B and the first drain extension region 172B.

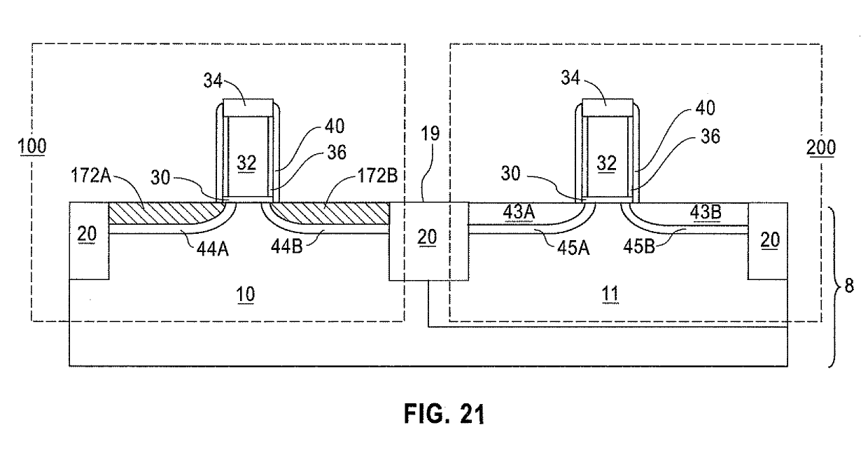

Referring to FIG. 21, the at least one mask layer (60, 62) are removed by an etch such as a wet etch or a reactive ion etch.

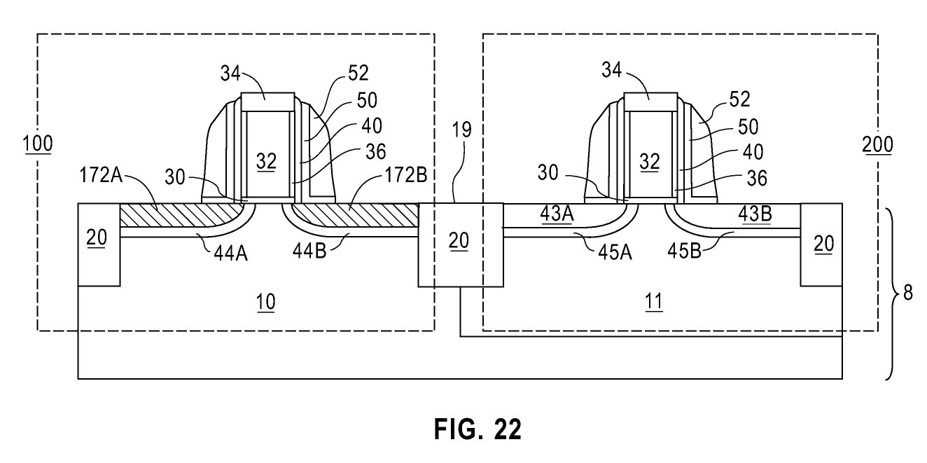

Referring to FIG. 22, a second gate spacer 50 and a third gate spacer 52 are formed on the gate electrodes (30, 32) of the first device 100 and the second device 200. The second gate spacer 50 and third gate spacer 52 may have the same structure and composition as in the first embodiment.

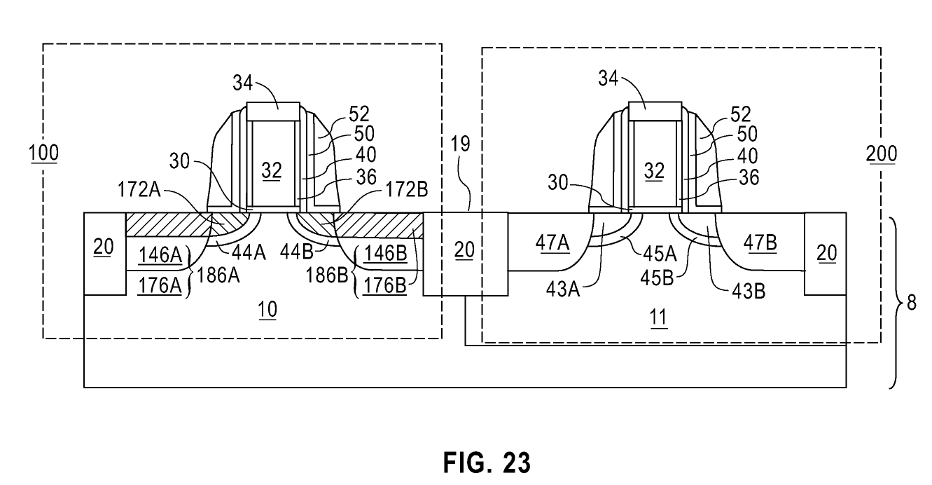

Referring to FIG. 23, masked source and drain ion implantations are sequentially performed to form various deep source and drain regions. Specifically, the second device 200 is masked with a photoresist (not shown), while exposing the first device by lithographical patterning of the photoresist. The first deep source region 186A and the second deep source region 186B are formed in the first device by ion implantation of dopants of the second conductivity type. The first deep source region 186A comprises a top source region 176A located above the extension depth De (See FIG. 19) and comprising the second semiconductor material and a bottom source region 146A located below the extension depth De and comprising the first semiconductor material. Likewise, the first deep drain region 186B comprises a top drain region 176B located above the extension depth De and comprising the second semiconductor material and a bottom drain region 146B located below the extension depth De and comprising the first semiconductor material. The first deep source region 186A and the first deep drain region 186B have a doping of the second conductivity type at a dopant concentration from about 3.0×10¹⁸/cm³ to about 3.0×10²¹/cm³, and typically from about 3.0×10¹⁹/cm³ to about 1.0×10²¹/cm³, although lesser and greater dopant concentrations are herein contemplated also. The photoresist is subsequently removed.

The first device 100 is masked with another photoresist (not shown), while exposing the second device 200 by lithographical patterning of the another photoresist. A second deep source region 47A and a second deep drain region 47B are formed in the second device 200 by ion implantation of dopants of the first conductivity type. The dopant concentration of the second deep source region 47A and the second deep drain region 47B may be the same as in the first embodiment.

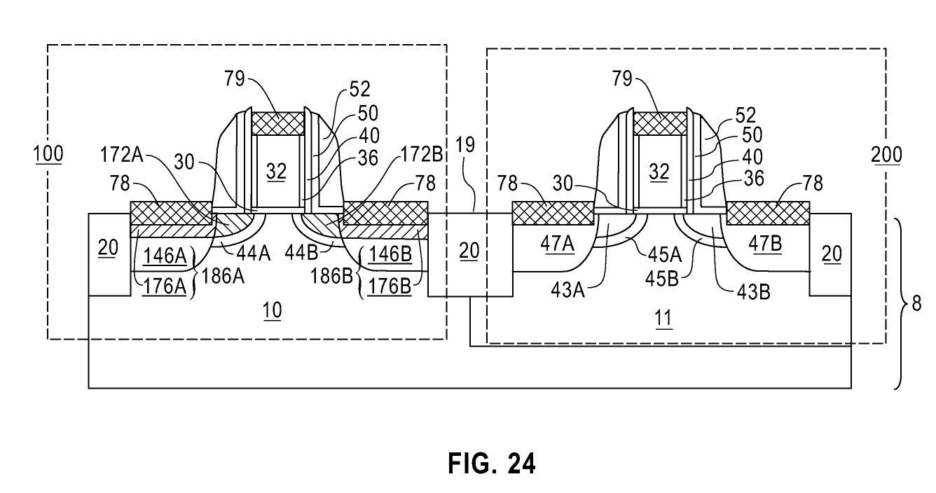

Referring to FIG. 24, various metal semiconductor alloys (78, 79) are formed as in the first embodiment.

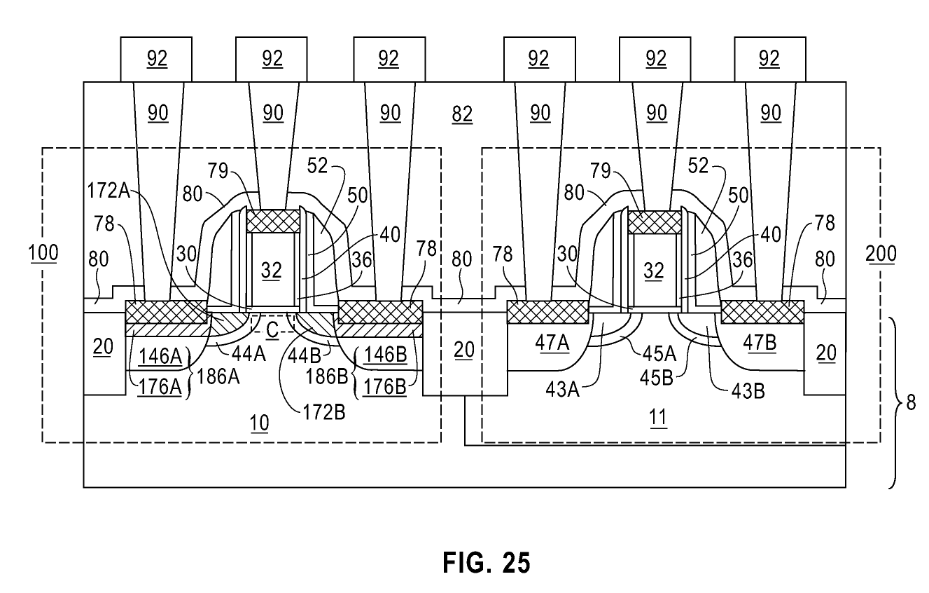

Referring to FIG. 25, a mobile ion diffusion barrier layer 80, a middle-of-line (MOL) dielectric layer 82, various contact vias 90, and a first level metal wiring 92 are formed as in the first exemplary semiconductor structure.

As in the first and second embodiments, the second semiconductor material applies a uniaxial stress in the channel region C of the first device 100 such that mobility of charge carriers is enhanced due to the uniaxial stress.

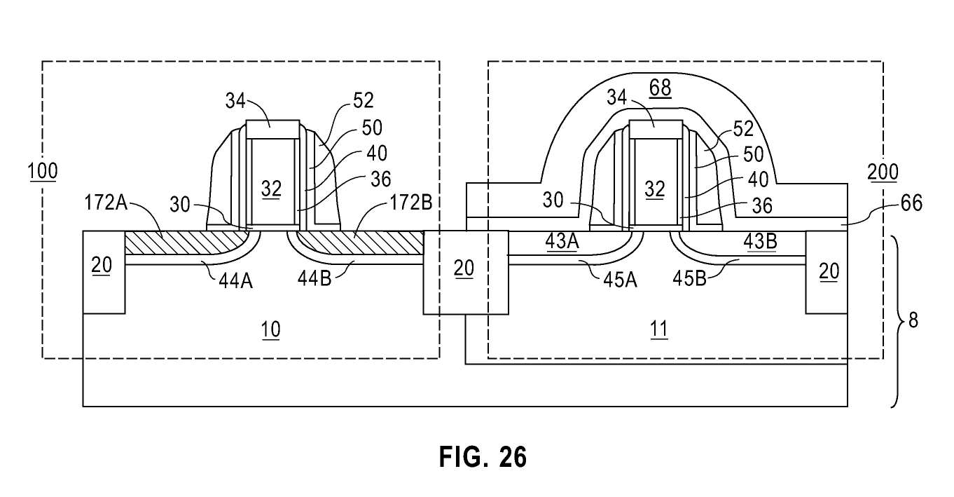

Referring to FIG. 26, a fourth exemplary semiconductor structure according to a fourth embodiment of the present invention is derived from the third exemplary semiconductor structure of FIG. 22 by forming another at least one mask layer which may comprise a third mask layer 66 and a fourth mask layer 68 over the second device 200, while exposing the first device 100. The third mask layer 66 and the fourth mask layer 68 may comprise a dielectric material. The third mask layer 66 may have the same thickness and composition as the first mask layer 60 of the first through third embodiments, while fourth mask layer 68 may have the same thickness and composition as the second mask layer 62 of the first through third embodiments.

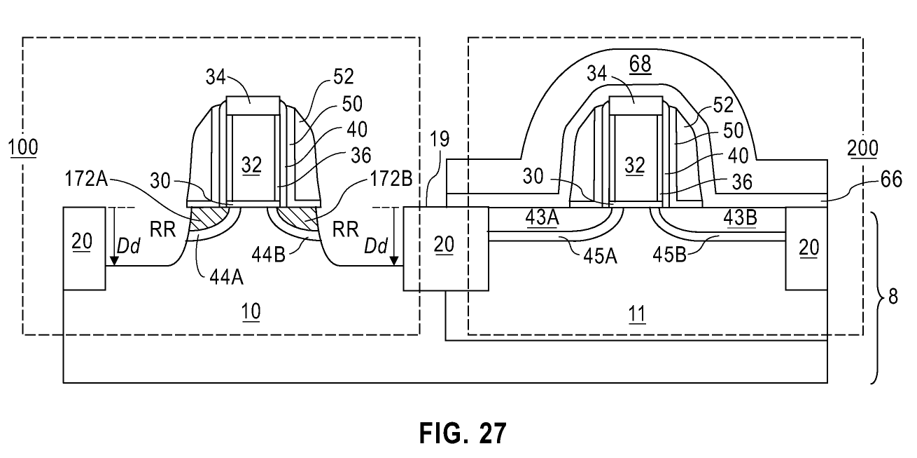

Referring to FIG. 27, recessed regions RR extending from a top surface 19 of the semiconductor substrate 8 to a deep source and drain depth Dd are formed by a reactive ion etch (RIE), a chemical dry ech (CDE), or a combination thereof Preferably, a reactive ion etch that forms substantially vertical surfaces that are self-aligned to the outer sidewalls of the at least one gate spacer (40, 50, 52) are employed to form the recessed regions RR.

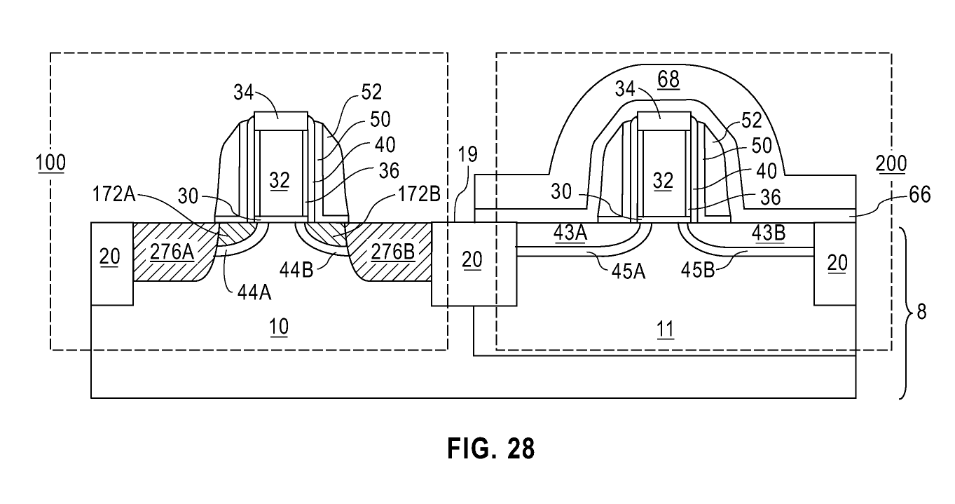

Referring to FIG. 28, a second selective epitaxy of the second semiconductor material is performed to form a first deep source region 276A and a first deep drain region 276B. Preferably, the second semiconductor material is in-situ doped with dopants of the second conductivity type at a dopant concentration from about 3.0×10¹⁸/cm³ to about 3.0×10²¹/cm³, and typically from about 3.0×10¹⁹/cm³ to about 1.0×10²¹/cm³, although lesser and greater dopant concentrations are herein contemplated also.

Heterojunctions are formed between the collective set of the first semiconductor region 10, the first source side halo region 44A, and the first drain side halo region 44B, and the collective set of the first source extension region 172A, the first drain extension region 172B, the first deep source region 276A, and the first deep drain region 276B. The heterojunctions coincide with, or are located in close proximity to, the p-n junctions since the collective set of the first semiconductor region 10, the first source side halo region 44A, and the first drain side halo region 44B has a doping of the first conductivity type, while the collective set of the first source extension region 172A, the first drain extension region 172B, the first deep source region 276A, and the first deep drain region 276B has a doping of the second conductivity type.

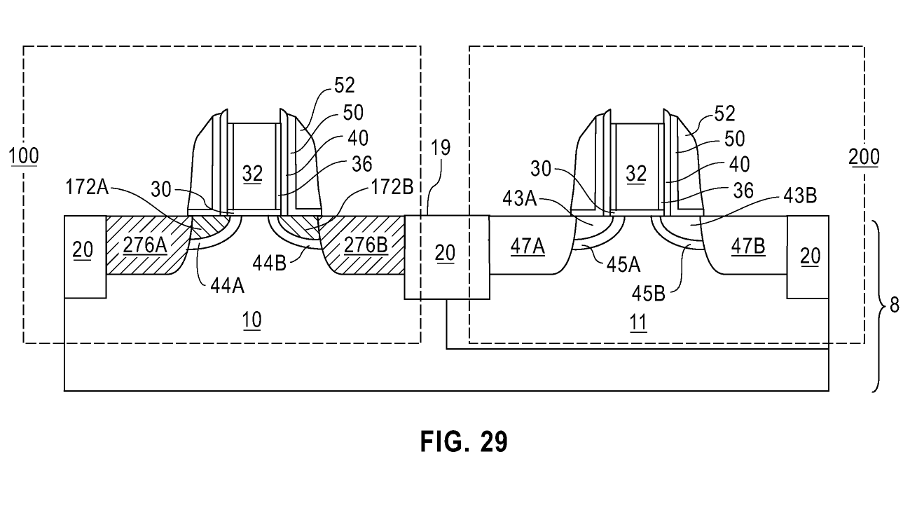

Referring to FIG. 29, the another at least one mask layer (66, 68) are removed by an etch such as a wet etch or a reactive ion etch. The gate cap dielectrics 34 are also removed.

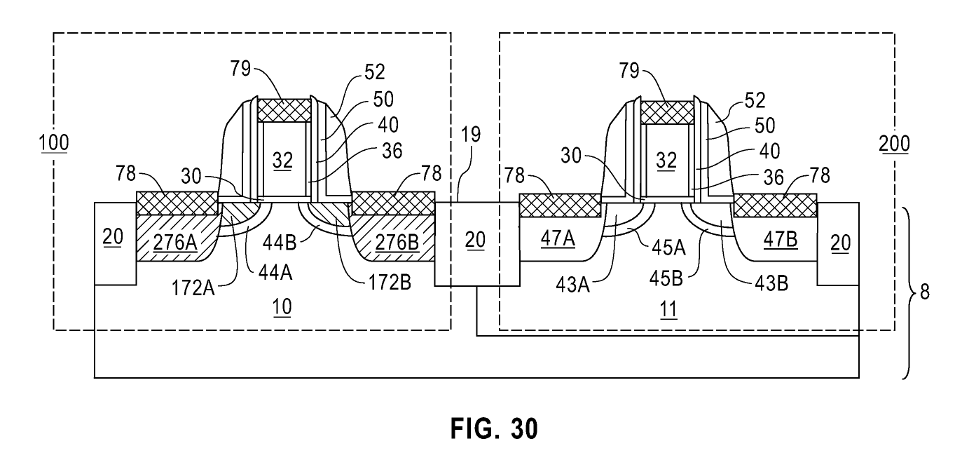

Referring to FIG. 30, various metal semiconductor alloys (78, 79) are formed as in the first though third embodiments.

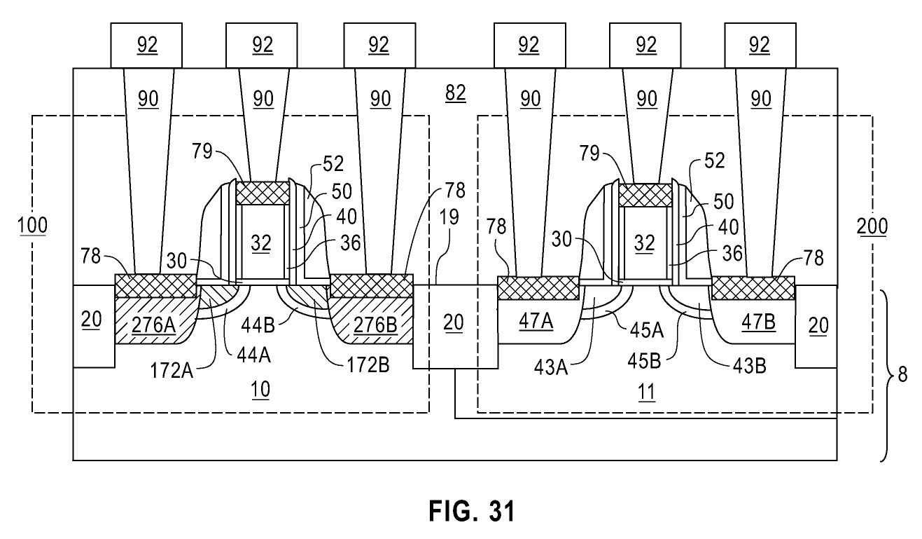

Referring to FIG. 31, a mobile ion diffusion barrier layer 80, a middle-of-line (MOL) dielectric layer 82, various contact vias 90, and a first level metal wiring 92 are formed as in the first through third exemplary semiconductor structures.

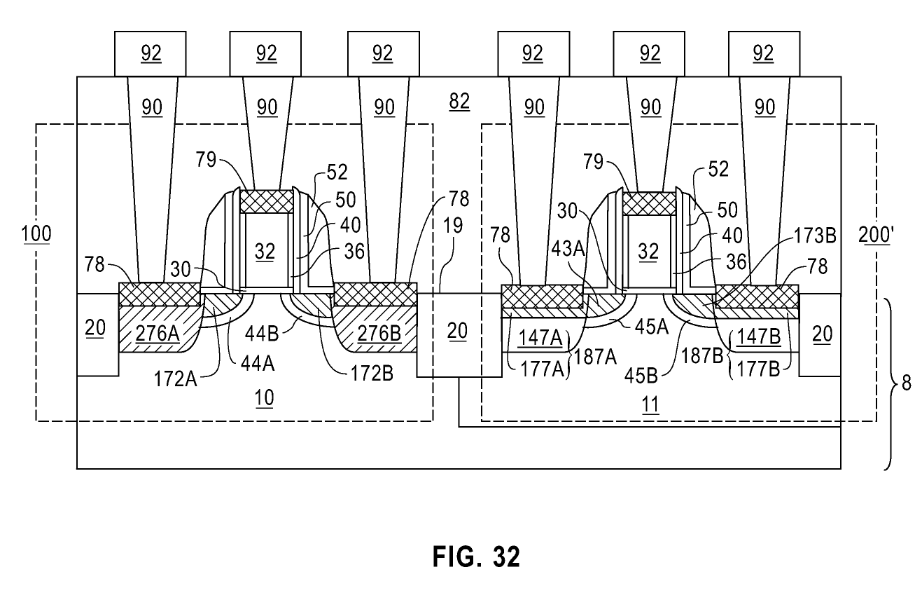

Referring to FIG. 32, a fifth exemplary semiconductor structure according to a fifth embodiment of the present invention comprises a combination of a first device 100 according to the fourth embodiment and a second device 200′ formed by methods of forming the first device 100 of the third embodiment with reversed dopant polarity by sequential masking of the first device 100 and the second device 200′. A third semiconductor material having a different composition than the first semiconductor material and the second semiconductor material are introduced at least into a second source extension region 173A and a second drain extension region 173B.

The second semiconductor device 200′ comprises:

a second semiconductor region 11, which is a body 11 having a doping of the second conductivity type, wherein the body 11 abuts the top surface of the semiconductor substrate 19;

a gate electrode including a gate dielectric (30 within 200′) and a gate conductor (32 within 200′), wherein the another gate dielectric 30 vertically abuts the body 11;

a second source extension region 173A and a drain extension region 173B, each of which comprising a third semiconductor material, having a doping of the first conductivity type, located in the semiconductor substrate 8, abutting the gate dielectric 30, and self-aligned to one of gate electrode sidewalls of the gate electrode (30, 32 within 200′), wherein the third semiconductor material is different from the first semiconductor material and the second semiconductor material; and

a deep source region 187A and a deep drain region 187B, each of which having a doping of the first conductivity type, located in the semiconductor substrate 8, laterally abutting one of the source extension region 173A and the drain extension region 173B, and self-aligned to one of gate spacer outer sidewalls of the at least one gate spacer (40, 50, 52 within 200′) of the gate electrode (30, 32 within 200′).

The first channel region C1 of the first device 100 is under a first uniaxial stress, which may be compressive or tensile, in the direction connecting the first source extension region 72A and the first drain extension region 172B. Likewise, the second channel region C2 of the second device 200′ is under a second uniaxial stress, which may be tensile or compressive, in the direction connecting the second source extension region 173A and the second drain extension region 173B. Preferably, the first uniaxial stress and the second uniaxial stress are of opposite types, i.e., one is compressive and the other is tensile.

In case the first semiconductor material comprises silicon, one of the second semiconductor material and the third semiconductor material may comprise a silicon germanium alloy and the other may comprise a silicon carbon alloy. For example, the first semiconductor material comprises silicon, the first device may be a p-type MOSFET, the second semiconductor material may be a silicon germanium alloy, and the first uniaxial stress may be a compressive stress so that hole mobility is enhanced due to the compressive uniaxial stress. At the same time, the second device 200′ may be an n-type MOSFET, the third semiconductor material may be a silicon carbon alloy, and the second uniaxial stress may be a tensile stress so that electron mobility is enhanced due to the tensile uniaxial stress. Embodiments in which the polarities of the first device 100 and the second device 200′ are reversed are explicitly contemplated herein.

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

What is claimed is:

1. A semiconductor structure comprising:
a semiconductor substrate containing a first semiconductor material and including a body having a doping of a first conductivity type, wherein said body abuts a top surface of said semiconductor substrate;
a gate electrode including a gate dielectric and a gate conductor, wherein said gate dielectric vertically abuts said body;
at least one gate spacer surrounding and laterally abutting said gate electrode and vertically abutting said top surface of said semiconductor substrate;
a source extension region and a drain extension region, each of which comprising a second semiconductor material, having a doping of a second conductivity type, located in said semiconductor substrate, abutting said gate dielectric, extending to a first depth into said semiconductor substrate from said top surface into said semiconductor substrate, and self-aligned to one of sidewalls of said gate electrode, wherein said second semiconductor material is different from said first semiconductor material; and
a deep source region and a deep drain region, each of which having a doping of said second conductivity type, located in said semiconductor substrate, laterally abutting one of said source extension region and said drain extension region, extending to a second depth from said top surface into said semiconductor substrate, and self-aligned to one of gate spacer outer sidewalls, wherein said second depth is greater than said first depth.

2. The semiconductor structure of claim 1, wherein said deep source region laterally abuts said source extension region, said deep drain region laterally abuts said drain extension region, and said source extension region and said drain extension region have a width that is substantially equal to a width of said at least one gate spacer.

3. The semiconductor structure of claim 1l wherein said deep source region and said deep drain region comprise said second semiconductor material.

4. The semiconductor structure of claim 3, wherein said deep source region comprises a vertical stack of a top source region and a bottom source region and said deep drain region comprises a vertical stack of a top drain region and a bottom drain region, wherein each of said top source region and said top drain region comprises said second semiconductor material and extends from said top surface of said semiconductor substrate to said first depth, and wherein each of said bottom source region and said bottom drain region comprises said first semiconductor material and extends from said first depth to said second depth.

5. The semiconductor structure of claim 3, wherein each of said deep source region and said deep drain region contains said second semiconductor material.

6. The semiconductor structure of claim 1, wherein said first semiconductor material is silicon and said second semiconductor material is one of a silicon germanium alloy, a silicon carbon alloy, and a silicon carbon germanium alloy.

7. The semiconductor structure of claim 1, further comprising:
a source side halo region having a doping of said first conductivity type, located directly beneath said source extension region and said gate electrode, and self-aligned to one of said sidewalls of said gate electrode; and
a drain side halo region having a doping of said first conductivity type, located directly beneath said drain extension region and said gate electrode, and self-aligned to another of said sidewalls of said gate electrode.

8. The semiconductor structure of claim 1, wherein each of said source extension region and said drain extension region abuts said body at a convexly arced surface extending from said gate dielectric to said first depth into said semiconductor substrate, wherein said convexly arced surface is free of crystallographic facets.

9. The semiconductor structure of claim 1, wherein said source extension region and said drain extension region generate stress in a channel located directly beneath said gate electrode and between said source extension region and said drain extension region, wherein said stress is a uniaxial stress in the direction connecting said source extension region and said drain extension region.

10. The semiconductor structure of claim 1, further comprising another semiconductor device located on said semiconductor substrate, said another semiconductor device comprising:
another body having a doping of said second conductivity type, wherein said another body abuts said top surface of said semiconductor substrate;
another gate electrode including another gate dielectric and another gate conductor, wherein said another gate dielectric vertically abuts said another body;
a source extension region and a drain extension region, each of which comprising said first semiconductor material, having a doping of said first conductivity type, located in said semiconductor substrate, abutting said another gate dielectric, and self-aligned to one of sidewalls of said another gate electrode; and
a deep source region and a deep drain region, each of which having a doping of said first conductivity type, located in said semiconductor substrate, laterally abutting one of said another source extension region and said another drain extension region, and self-aligned to one of sidewalls of another gate spacer on said another gate electrode.

11. The semiconductor structure of claim 1, further comprising another semiconductor device located on said semiconductor substrate, said another semiconductor device comprising:
another body having a doping of said second conductivity type, wherein said another body abuts said top surface of said semiconductor substrate;
another gate electrode including another gate dielectric and another gate conductor, wherein said another gate dielectric vertically abuts said another body;
a source extension region and a drain extension region, each of which comprising a third semiconductor material, having a doping of said first conductivity type, located in said semiconductor substrate, abutting said another gate dielectric, and self-aligned to one of sidewalls of said another gate electrode, wherein said third semiconductor material is different from said first semiconductor material and said second semiconductor material; and
a deep source region and a deep drain region, each of which having a doping of said first conductivity type, located in said semiconductor substrate, laterally abutting one of said another source extension region and said another drain extension region, and self-aligned to one of outer sidewalls of another gate spacer on said another gate electrode.

12. A method of forming a semiconductor structure comprising:
providing a semiconductor region comprising a first semiconductor material and having a doping of a first conductivity type in a semiconductor substrate;
forming a gate electrode containing a gate dielectric and a gate conductor on said semiconductor substrate;
forming a dummy source extension region and a dummy drain extension region by implanting dopants of a second conductivity type into said semiconductor region, wherein each of said dummy source extension region and said dummy drain extension region has a doping of said second conductivity type and extends from a top surface of said semiconductor substrate to a first depth, and wherein said second conductivity type is the opposite of said first conductivity type;
forming a source side halo region and a drain side halo region, each of which having a doping of said first conductivity type and extending from said top surface of said semiconductor substrate to a halo depth in said semiconductor region, wherein said halo depth is greater than said first depth, said source extension region abut said source side halo region, and said drain extension region abut said drain side halo region;
removing said dummy source extension region and said dummy drain extension region selective to said source side halo region and said drain side halo region; and
selectively depositing a second semiconductor material directly on said source side halo region and said drain side halo region, wherein said second semiconductor material is different from said first semiconductor material.

13. The method of claim 12, further comprising:
forming a dummy deep source region and a dummy deep drain region, each of which having a doping of said second conductivity type and extending from said top surface of said semiconductor substrate to a second depth, which is greater than said halo depth;
removing said dummy deep source region and said dummy deep drain region selective to a portion of said semiconductor region having said doping of said first conductivity type; and
selectively depositing said second semiconductor material directly on said portion of said semiconductor region.

14. The method of claim 12, further comprising:
forming at least one gate spacer on said gate electrode and directly on a portion of said second semiconductor material; and
forming a deep source region and a deep drain region, each of which having a doping of said second conductivity type, by implanting dopants of said second conductivity type into said semiconductor substrate, wherein said deep source region comprises a vertically abutting stack of a top source region comprising said second conductive material and a bottom source region comprising said first conductivity material, and wherein said seep drain region comprises a vertically abutting stack of a top drain region comprising said second conductive material and a bottom drain region comprising said first conductivity material.

15. The method of claim 12, further comprising:
forming at least one gate spacer on said gate electrode and directly on a portion of said second semiconductor material;
removing a source side recessed region and a drain side recessed region by etching exposed portions of said second semiconductor material, wherein two portions of said second semiconductor material remain directly beneath said gate electrode and said at least one gate spacer; and
selectively depositing said second semiconductor material within said source side recessed region and said drain side recessed region.

16. The method of claim 12, further comprising forming another semiconductor device on said semiconductor substrate, said another semiconductor device comprising:
another body having a doping of said second conductivity type, wherein said another body abuts said top surface of said semiconductor substrate;
another gate electrode including another gate dielectric and another gate conductor, wherein said another gate dielectric vertically abuts said another body;
a source extension region and a drain extension region, each of which comprising said first semiconductor material, having a doping of said first conductivity type, located in said semiconductor substrate, abutting said another gate dielectric, and self-aligned to one of gate electrode sidewalls of said another gate electrode; and
a deep source region and a deep drain region, each of which having a doping of said first conductivity type, located in said semiconductor substrate, laterally abutting one of said another source extension region and said another drain extension region, and self-aligned to one of gate spacer outer sidewalls of said another gate electrode.

17. The method of claim 12, further comprising forming another semiconductor device on said semiconductor substrate, said another semiconductor device comprising:
another body having a doping of said second conductivity type, wherein said another body abuts said top surface of said semiconductor substrate;
another gate electrode including another gate dielectric and another gate conductor, wherein said another gate dielectric vertically abuts said another body;
a source extension region and a drain extension region, each of which comprising a third semiconductor material, having a doping of said first conductivity type, located in said semiconductor substrate, abutting said another gate dielectric, and self-aligned to one of gate electrode sidewalls of said another gate electrode, wherein said third semiconductor material is different from said first semiconductor material and said second semiconductor material; and
a deep source region and a deep drain region, each of which having a doping of said first conductivity type, located in said semiconductor substrate, laterally abutting one of said another source extension region and said another drain extension region, and self-aligned to one of gate spacer outer sidewalls of said another gate electrode.

18. The method of claim 12, wherein said first semiconductor material is silicon and said second semiconductor material comprises one of silicon germanium alloy, silicon carbon alloy, and silicon germanium carbon alloy.

19. A method of forming a semiconductor structure comprising:
providing a semiconductor region comprising a first semiconductor material and having a doping of a first conductivity type at a first dopant concentration in a semiconductor substrate;
forming a gate electrode containing a gate dielectric and a gate conductor on said semiconductor substrate;
forming a dummy source extension region and a dummy drain extension region by implanting dopants of said first conductivity type into said semiconductor region, wherein each of said dummy source extension region and said dummy drain extension region has a doping of said first conductivity type at a second dopant concentration, extends from a top surface of said semiconductor substrate to a first depth, and abuts a portion of said semiconductor region having said first dopant concentration, wherein said second dopant concentration is greater than said first dopant concentration;
removing said dummy source extension region and said dummy drain extension region selective to said portion of said semiconductor region having said first dopant concentration; and
selectively depositing a second semiconductor material directly on said source side halo region and said drain side halo region, wherein said second semiconductor material is different from said first semiconductor material.

20. The method of claim 19, further comprising:
forming a dummy deep source region and a dummy deep drain region, each of which having a doping of said first conductivity type at a third dopant concentration and extending from said top surface of said semiconductor substrate to a second depth, which is greater than said first depth, wherein said third dopant concentration is greater than said first dopant concentration;
removing said dummy deep source region and said dummy deep drain region selective to said portion of said semiconductor region having said doping of said first conductivity type;
selectively depositing said second semiconductor material directly on said portion of said semiconductor region; and
forming a source side halo region and a drain side halo region directly beneath two portions of said second semiconductor material.
